(19) United States
(12) Patent Application Publication
(10) Pub. No.: US 2014/0105767 A1
(43) Pub. Date: Apr. 17, 2014

(54) POWER SUPPLY MODULE

(71) Applicant: DENSO CORPORATION, Kariya-city (JP)

(72) Inventors: Akira IWABUCHI, Kariya-city (JP); Masao Yamada, Kariya-city (JP); Kenji Onoda, Anjo-city (JP); Satoru Sugita, Kariya-city (JP); Takayoshi Sakashita, Kariya-city (JP)

(73) Assignee: DENSO CORPORATION, Kariya-city (JP)

(21) Appl. No.: 14/052,810

(22) Filed: Oct. 14, 2013

(30) Foreign Application Priority Data
Oct. 16, 2012 (JP) 2012-229211
Oct. 23, 2012 (JP) 2012-233958

(51) Int. Cl. H05K 7/00

(52) U.S. Cl. CPC H05K 7/00
USPC 417/410.1; 361/728

(57) ABSTRACT

A power supply module configured to supply power to a load having a first connector terminal includes a body, an insulating member, and a second connector terminal. The body includes a frame for power supply. The insulating member seals the body such that the frame is exposed from the insulating member. The second connector terminal is configured to be fitted with the first connector terminal and is bonded to the frame.

### CROSS REFERENCE TO RELATED APPLICATIONS

The present application is based on and claims priority to Japanese Patent Application No. 2012-229211 filed on Oct. 16, 2012 and Japanese Patent Application No. 2012-233958 filled on Oct. 23, 2012, the contents of which are incorporated in their entirety herein by reference.

### TECHNICAL FIELD

The present disclosure relates to a power supply module that is configured to supply power to a load and includes a body sealed with an insulating member.

### BACKGROUND

A power supply module configured to supply power to a load and sealed with an insulating member is disclosed, for example, in JP-A-2004-524701 (corresponding to U.S. Pat. No. 7,046,518), JP-A-2011-187819, JP-A-2010-129550 (corresponding to U.S. Pat. No. 8,319,333), and JP-A-2011-77280.

FIG. 38 is a diagram showing an example of a usage form of a conventional power supply module (inverter module) 20 that supplies power to an electric compressor having an electromechanical integral structure. The power supply module 20 is assembled to a cover 11b that is disposed on a housing 11a of a driving motor 10.

FIG. 39 is a cross-sectional view showing a part in the vicinity of a second connector terminal 50a of a connector 50 in FIG. 38. In FIG. 38 and FIG. 39, a vertical direction is reversed.

A recent electric compressor in a vehicle air-conditioning system employs an electromechanical integral structure to reduce a size, and a driving motor of a compressor and a power supply module for supplying power to the driving module are disposed in a pair of housing.

As shown in FIG. 38, in the electric compressor having the electromechanical integral structure, a three-phase driving motor 10 for driving the compressor is sealed in a housing 11a in which a coolant circulates. Thus, power is supplied to the driving motor 10 via three first connector terminals T1 that penetrate through the housing 11a and are sealed air-tightly. As shown in FIG. 39, the first connector terminals T1 are generally cylindrical male terminals.

The power supply module 20 for supplying power to the driving motor 10 as a load is attached to the cover 11b in a state where the power supply module 20 is fixed to a heat radiation member 30 with screws and is mounted to a printed circuit board 40. The power supply module 20 is sealed with insulating resin (molded resin) by transfer molding. Lead frames, which include output terminals protruding from the molded resin, are bonded to a wiring pattern of the printed circuit board 40 by soldering. The connector 50 has the second connector terminals 50a to be fitted with the first connector terminals. The connector 50 is mounted on the printed circuit board 40. Output leads L1 of the power supply module 20 and leads L2 connected to the second connector terminals 50a of the connector 50 are electrically connected with the wiring pattern of the printed circuit board 40.

When the cover 11b attached with the printed circuit board 40 is disposed on the housing 11a of the driving motor 10, the first connector terminals T1 and the second connector terminals 50a are fitted with each other, and the power supply module 20 and the driving motor 10 are electrically connected with each other. At the same time, the heat radiation member 30 comes into contact with the housing 11a.

As shown in FIG. 38 and FIG. 39, the second connector terminals 50a are disposed in an insulating member (mold resin) 50b formed by transfer molding. In the assembling structure shown in FIG. 38, center axes of the first connector terminals T1 and center axes of the second connector terminals 50a may be displaced from appropriate fitting positions due to, for example, assembling errors. Thus, as shown in FIG. 39, on a lower surface of the insulating member 50b of the connector 50, guides 50c having taper shapes are provided around insertion holes 50d so as to facilitate insertion of the first connector terminals T1. Because the printed circuit board 40 moves along the guides 50c, the first connector terminals T1 and the second connector terminals 50a are easily fitted with each other.

In the connection structure of the power supply module 20 and the driving motor 10 shown in FIG. 38, there are a lot of solder connection points on a power supply line from the power supply module 20 to the driving motor 10. The solder connection points have high impedance and may generate heat when a large current flows. The printed circuit board 40 needs mounting spaces of the power supply module 20 and the connector 50 and a wiring space of wirings for connecting the power supply module 20 and the connector 50. Thus, a size of the printed circuit board 40 becomes large. As a method for solving the above-described issues, the load and the power supply module may be directly connected with each other only by the second connector terminals 50a fitted with the first connector terminals T1 of the load, without via the printed circuit board 40.

However, also in this case, the power supply module needs a simple and inexpensive mechanism for restricting displacement from the appropriate fitting positions due to, for example, assembling errors of the first connector terminals T1 and the second connector terminals 50a, such as the guides 50c and the total displacement of the printed circuit board 40.

### SUMMARY

It is an object of the present disclosure to provide a power supply module that includes a body sealed with an insulating member and can be electrically connected with an arbitrary load without via a printed circuit board. Another object of the present disclosure is to provide a power supply module that can restrict displacement of a first connector terminal of a load from an appropriate fitting position.

A power supply module according to a first aspect of the present disclosure is configured to supply power to a load having a first connector terminal, and includes a body, an insulating member, and a second connector terminal. The body includes a frame for power supply. The insulating member seals the body such that the frame is exposed from the insulating member. The second connector terminal is configured to be fitted with the first connector terminal and is bonded to the frame.

In the power supply module, the second connector terminal is bonded to the frame for power supply exposed from the insulating member. Thus, the power supply module can be electrically connected with the load without via a printed circuit board.

A power supply module according to a second aspect of the present disclosure is configured to supply power to a load having a first connector terminal and includes a body and an insulating member. The insulating member seals the body and has a through hole through which the first connector terminal is inserted.

In the power supply module, the through hole can have a function of positioning the first connector terminal. Thus, the power supply module can restrict displacement of the first connector terminal.

### BRIEF DESCRIPTION OF THE DRAWINGS

Additional objects and advantages of the present disclosure will be more readily apparent from the following detailed description when taken together with the accompanying drawings. In the drawings:

FIG. 1 is a cross-sectional view showing an assembling structure of a power supply module according to a first embodiment of the present disclosure to a cover to be disposed on a housing of a driving motor;

FIG. 2A is a perspective view of a power supply module according to a concrete example of the first embodiment, FIG. 2B is an enlarged perspective view of a part of the power supply module shown in FIG. 2A, and FIG. 2C is an enlarged perspective view of a part of the power supply module shown in FIG. 2A;

FIG. 3 is a perspective view of a body of the power supply module before second connector terminals are joined;

FIG. 4A is a perspective view of a second connector terminal, FIG. 4B is a perspective view of a contact piece section, FIG. 4C is a perspective view of a cylindrical spring section, FIG. 4D is a perspective view showing a state where the cylindrical spring section is attached to the contact piece section, and FIG. 4E is a perspective view of a cylindrical guide section;

FIG. 5A and FIG. 5B are perspective views of a part in the vicinity of second connector terminals of a power supply module according to a first modification of the first embodiment viewed from above and below;

FIG. 6 is a perspective view of a second connector terminal in the power supply module shown in FIG. 5A and FIG. 5B;

FIG. 7A and FIG. 7B are diagrams showing processes of manufacturing the second connector terminal shown in FIG. 6;

FIG. 8A to FIG. 8D are diagrams showing processes of manufacturing the second connector terminal shown in FIG. 6;

FIG. 9A and FIG. 9B are diagrams showing processes of welding the second connector terminal to a body;

FIG. 10A to FIG. 10C are diagrams showing processes of welding the second connector terminal to the body;

FIG. 11A is a perspective view of a second connector terminal according to a second modification of the first embodiment, and FIG. 11B is a perspective view of a second connector terminal according to a third modification of the first embodiment;

FIG. 12A is a perspective view of a power supply module according to a fourth modification of the first embodiment before a terminal cover is attached, FIG. 12B is a perspective view of the power supply module after the terminal cover is attached, and FIG. 12C is an enlarged view of a part in the vicinity of an insertion hole of the terminal cover;

FIG. 13A is a perspective view of a power supply module according to a fifth modification of the first embodiment before a terminal cover is attached, FIG. 13B is a diagram showing arrangement of screws and nuts for fixing a terminal cover, and FIG. 13C is a perspective view of the power supply module viewed from a rear side after the terminal cover is fixed with the screws and the nuts;

FIG. 14A is a perspective view of a power supply module according to a sixth modification of the first embodiment before a terminal cover is attached, FIG. 14B is a perspective view of the power supply module after the terminal cover is attached, and FIG. 14C is an enlarged view of a part in the vicinity of an insertion hole of the terminal cover;

FIG. 15A is an enlarged view of a part in the vicinity of second connector terminals of a power supply module according to a seventh modification of the first embodiment, FIG. 15B is a perspective view of a body before the second connector terminals are joined, and FIG. 15C is a perspective view of the second connector terminal;

FIG. 16A is a perspective view of the power supply module according to the seventh modification before a terminal cover is attached, and FIG. 16B is a perspective view of the power supply module after the terminal cover is attached;

FIG. 17A is an enlarged view of a part in the vicinity of second connector terminals of a power supply module according to an eighth modification of the first embodiment, FIG. 17B is a perspective view of a body before the second connector terminals are joined, and FIG. 17C is a perspective view of the second connector terminal;

FIG. 18A is a perspective view of the power supply module according to the eighth modification after a heat radiation member is attached and before a pair of terminal covers are attached, FIG. 18B is a perspective view of the power supply module after a first terminal cover is attached, and FIG. 180 is a perspective view of the power supply module after a second terminal cover is attached;

FIG. 19A is a perspective view of the power supply module viewed from above the first terminal cover, and FIG. 19B is a perspective view of the power supply module viewed from below the second terminal cover;

FIG. 20A is an enlarged view of a part in the vicinity of second connector terminals of a power supply module according to a ninth modification of the first embodiment, FIG. 20B is a perspective view of a body before the second connector terminals are joined, and FIG. 20C is a perspective view of the second connector terminal;

FIG. 21A is a perspective view of the power supply module according to the ninth modification after a heat radiation member is attached and before a pair of terminal covers are attached, FIG. 21B is a perspective view of the power supply module after a first terminal cover is attached, and FIG. 21C is a perspective view of the power supply module after a second terminal cover is attached;

FIG. 22 is a perspective view of the power supply module viewed from above the second terminal cover;

FIG. 23A is a perspective view of a power supply module according to a tenth modification of the first embodiment, and FIG. 23B is a perspective view of a body of the power supply module before second connector terminals are joined;

FIG. 24A is a perspective view of the second connector terminal according to the tenth modification of the first embodiment, and FIG. 24B is a perspective view of the second connector terminal viewed from a different angle;

FIG. 25 is a cross-sectional view showing an assembling structure of a power supply module according to a second embodiment of the present disclosure to a cover to be disposed on a housing of a driving motor;

FIG. 26A is a perspective view of a power supply module according to a concrete example of the second embodiment, FIG. 26B is an enlarged perspective view of a part of the power supply module shown in FIG. 26A;

FIG. 27 is a perspective view of a body of the power supply module before second connector terminals are joined;

FIG. 28A is a perspective view of a second connector terminal, FIG. 28B is a perspective view of the second connector terminal viewed from a different angle, FIG. 28C is a perspective view of a contact piece section, FIG. 28D is a perspective view of a cylindrical spring section, FIG. 28E is a perspective view showing a state where the cylindrical spring section is attached to the contact piece section, and FIG. 28F is a perspective view of a cylindrical guide section;

FIG. 29A is a perspective view showing a fitting state of a first connector terminal and the second connector terminal, and FIG. 29B is a perspective view showing an assembling relationship of a frame, the second connector terminal, and the first connector terminal;

FIG. 30A is a perspective view of a power supply module according to a first modification of the second embodiment viewed from above, and FIG. 30B is a perspective view of the power supply module viewed from below;

FIG. 31 is an enlarged perspective view of a part of the power supply module shown in FIG. 30A;

FIG. 32A is a perspective view of the power supply module according to the first modification of the second embodiment viewed from above before second connector terminals are joined, and FIG. 328 is a perspective view of the power supply module viewed from below before second connector terminals are joined;

FIG. 33 is a perspective view of the second connector terminal in the power supply module according to the first modification of the second embodiment;

FIG. 34A to FIG. 34C are diagrams showing processes of manufacturing the second connector terminal shown in FIG. 33;

FIG. 35A to FIG. 35C are diagrams showing processes of manufacturing the second connector terminal shown in FIG. 33;

FIG. 36 is a perspective view of a part of a power supply module according to a second modification of the second embodiment;

FIG. 37 is a perspective view of a second connector terminal in the power supply module shown in FIG. 36;

FIG. 38 is a cross-sectional view showing an assembling structure of a power supply module according to a prior art to a cover to be disposed on a housing of a driving motor; and

FIG. 39 is a cross-sectional view showing a part in the vicinity of a second connector terminal in the power supply module shown in FIG. 38.

### DETAILED DESCRIPTION

Power supply modules according to exemplary embodiments of the present disclosure will be described with reference to the accompanying drawings.

### First Embodiment

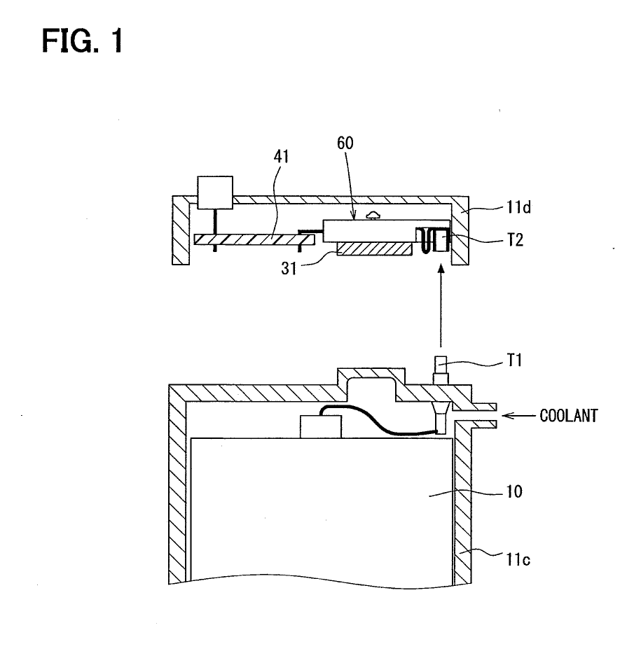

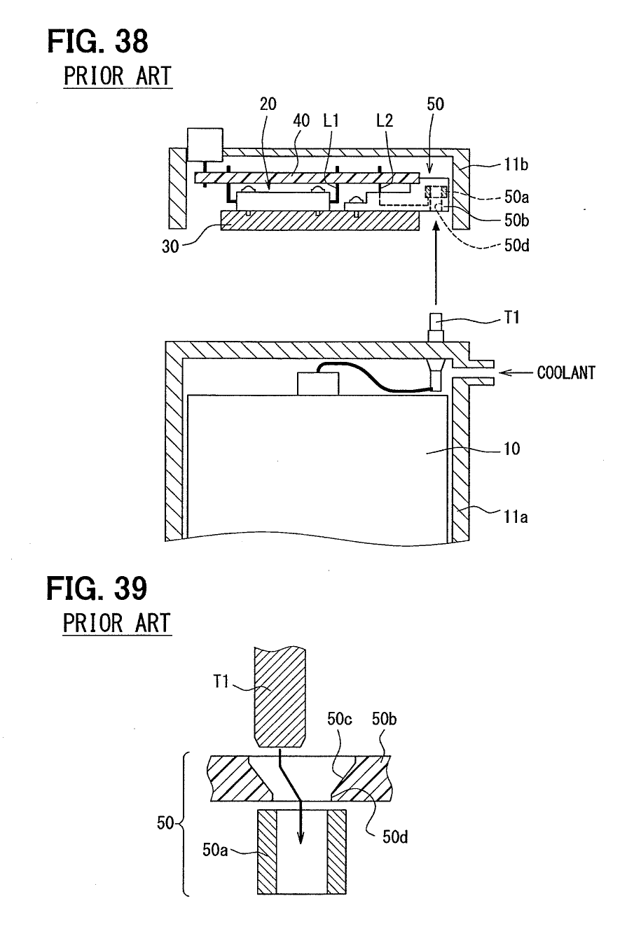

FIG. 1 is a diagram showing a usage example of a power supply module 60 according to a first embodiment of the present disclosure. The power supply module 60 can be used as an inverter module that supplied power to an electric compressor having an electromechanical integral structure. The power supply module 60 is assembled to a cover 11d disposed on a housing 11c of a driving motor 10 and supplies power to the driving motor 10 as a load. In the configuration in FIG. 1, components similar to the components shown in FIG. 38 are denoted by the same reference numerals.

In the electric compressor shown in FIG. 1, the three-phase driving motor 10 driving a compressor is sealed in the housing 11c in which a coolant circulates. Thus, the driving motor 10 is supplied with power via three first connector terminals T1 that penetrate the housing 11c and are sealed air-tightly. As shown in FIG. 1, the first connector terminals T1 are generally cylindrical male terminals.

The power supply module 60 includes second connector terminals T2. The second connector terminals T2 are female terminals fitted with the first connector terminals T1. The second connector terminals T2 are bonded to a frame. When the cover 11d attached with the power supply module 60 is disposed on the housing 11c of the driving motor 10, the first connector terminals T1 are fitted with the second connector terminals T2, and the power supply module 60 is electrically connected with the driving motor 10. At the same time, a heat radiation member 31 fixed to the power supply module 60 comes into contact with the housing 11c.

In the power supply module 60, the second connector terminals T2 fitted with the first connector terminals T1 of the load are directly bonded to the frame exposed from an insulating member that seals a body of the power supply module 60, without via a power supply line such as a printed circuit board.

The power supply module 60 is electrically connected with the driving motor 10 without via a printed circuit board differently from the structure shown in FIG. 38. Thus, the solder connection points on the power supply line in the printed circuit board 40, which causes a problem when the conventional power supply module 20 is used, can be eliminated. Also in the configuration shown in FIG. 1, a printed circuit board 41 is used. However, the printed circuit board 41 is a small board in which a power source wiring and a communication wiring to the power supply module 60 are formed. The second connector terminals T2 in the power supply module 60 are attached to the body of the power supply module 60 sealed with the insulating member and is disposed outside the insulating member. Thus, a degree of freedom of the shape of the second connector terminals T2 tailored to the first connector terminals T1 is high.

As described above, the power supply module 60 is configured to supply power to the load, includes the body sealed with the insulating member, and can be connected with an arbitrary load without via a printed circuit board. Thus, when the power supply module 60 shown in FIG. 1 is used, the issues caused in a case where the conventional power supply module 20 shown in FIG. 38 is used can be solved.

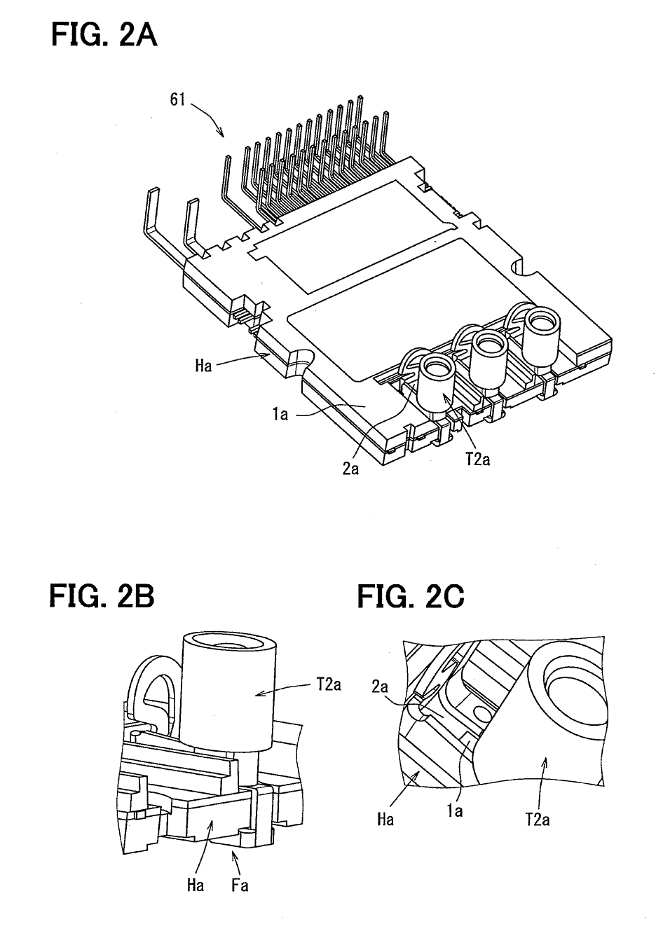

Next, a configuration of a power supply module 61 as a concrete example of the power supply module 60 will be described with reference to FIG. 2A to FIG. 4E.

The power supply module 61 shown in FIG. 2A supplies power to a load (e.g., the driving motor 10 shown in FIG. 1) and includes a body Ha sealed with an insulating member (molded resin) 1a by transfer molding. In the power supply module 61, the second connector terminals T2, which are female terminals, are bonded to frames 2a for power supply exposed from the insulating member 1a. The first connector terminals T1 of the load are inserted into the second connector terminals T2a from above in FIG. 2A, and the first connector terminals T1 are fitted with the second connector terminals T2a.

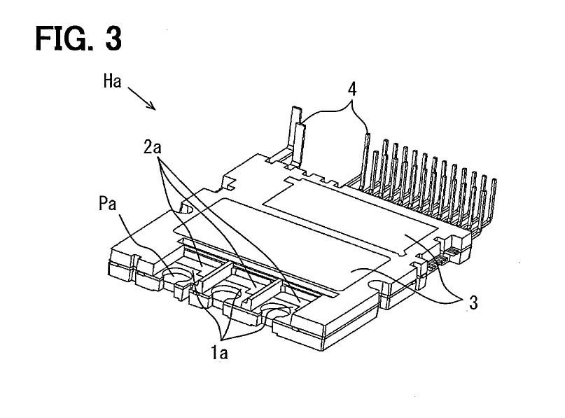

The power supply module 61 is a three-phase alternating current inverter. As shown in FIG. 3, the body Ha of the power supply module 61 is sealed with the insulating member 1a. Three frames 2a respectively corresponding to output terminals of a U-phase, a V-phase, a W-phase are exposed from the insulating member 1a. A heat radiation plate formed of another frame is embedded in the insulating member 1a. The heat radiation member 31 shown in FIG. 1 is fixed on a heat radiation surface 3 of the heat radiation plate. Lead frames for power supply and control are bent into L-shapes and are connected to the printed circuit board 41 shown in FIG. 1.

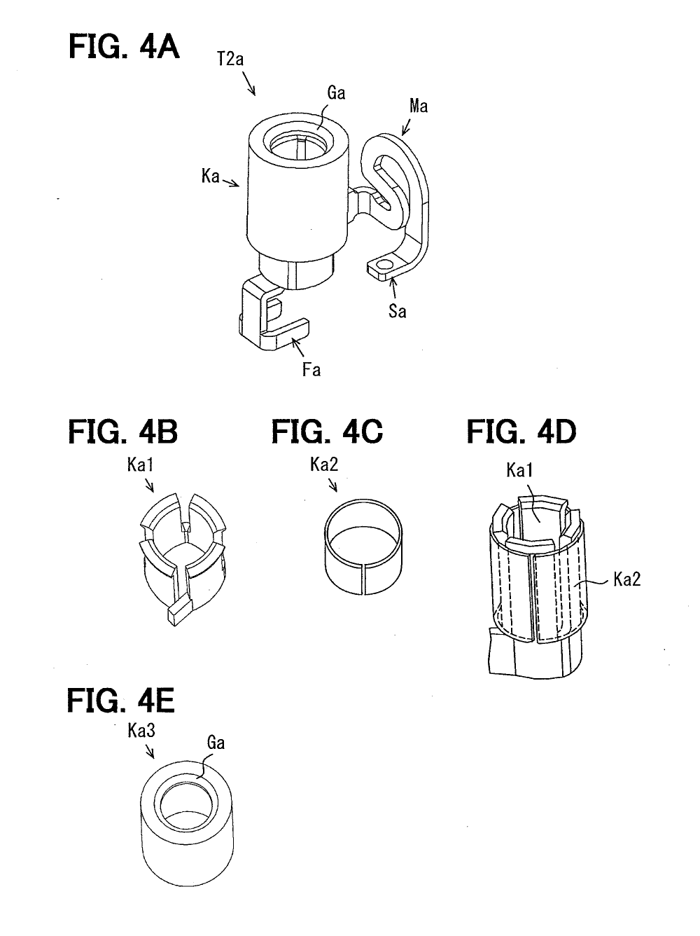

As shown in FIG. 4A, the second connector terminals T2a includes a joint section Sa, a fitting section Ka, an arm section Ma, and a hook section Fa. The joint section Sa is bonded to the frame 2a. The fitting section Ka is fitted with the first connector terminal T1 of the load. A current path of the second connecter terminal T2a to the load passes from the joint section Sa to the fitting section Ka via the arm section Ma.

The joint section Sa is bonded to the frame 2a exposed from the insulating member 1a sealing the body Ha. The joint section Sa of the second connector terminal T2a has a projection shape for projection welding.

The fitting section Ka is a female terminal fitted with the first connector terminal T1, which is the male terminal. The fitting section Ka includes a contact piece section Ka1 shown in FIG. 4B and a cylindrical spring section Ka2 shown in FIG. 4C. The contact piece section Ka1 includes four pieces connected at a bottom portion and has a ring shape. The cylindrical spring section Ka2 has a cylindrical shape and has a spring property. The contact piece section Ka1 is covered with the cylindrical spring section Ka2. The contact piece section Ka1 is formed by punching press from one plate with the arm section Ma, the joint section Sa, and the hook section Fa, and is bent into the ring shape. The contact piece section Ka1 has a protruding portion that protrudes from the bottom portion connecting the four pieces. The protruding portion is connected with the arm section Ma. The contact piece section Ka1 is covered with the cylindrical spring section Ka2 as shown in FIG. 4D. In addition, the contact piece section Ka1 and the cylindrical spring section Ka2, which are assembled as shown in FIG. 4D, is covered with a cylindrical guide section Ka3 shown in FIG. 4E. Accordingly, the fitting section Ka is assembled as shown in FIG. 4A. The cylindrical guide section Ka3 has a guide Ga having a taper shape. The guide Ga facilitates insertion of the first connector terminal T1 and leads the first connector terminal T1 to a fitting position. When the first connector terminal T1 of the load is inserted into a center of the contact piece section Ka1, a fitting structure having four contact beams is formed. Accordingly, a usable supply current can be increased compared with a case where contact beams are two beams.

The arm section Ma is elastically deformable and connects the joint section Sa and the fitting section Ka. When the fitting section Ka is fitted with the first connector terminal T1, the arm section Ma corrects a gap between center positions of the fitting section Ka and the first connector terminal T1. Because the first connector terminal T1 is fixed, the position of the fitting section Ka is adjusted with elastic deformation of the arm section Ma. Accordingly, the fitting section Ka is smoothly fitted with the first connector terminal T1. Specifically, when the first connector terminal T1 is inserted into the fitting section Ka, a displacement generated by the position correction of the fitting section Ka is caused by the elastic deformation of the arm section Ma because the joint section Sa is fixed by welding. The second connector terminal T2a is designed such that the arm section Ma and the hook section Fa deform more easily than the fitting section Ka and a connection reliability and a connection resistance value of the fitting portion Ka are maintained. The shape of the arm section Ma depends on the joint section Sa bonded to the frame 2a. The arm section Ma has an approximately S-shape.

In the second connector terminal T2a, because the arm section Ma, which is elastically deformable, is provided between the joint section Sa and the fitting section Ka, even if there is a positional gap or an angular gap with respect to the first connector terminal T1 when the first connector terminal T1 is fitted into the second connector terminal T2a, the gap can be absorbed by the elastic deformation of the arm section Ma. Thus, even if there is a positional gap or an angular gap when the first connector terminal T1 is fitted into the second connector terminal T2a, unexpected stress is not generated at the joint section Sa and the fitting section Ka of the second connector terminal T2a, and a stable electrical connection can be maintained.

When the first connector terminal T1 is pulled out from the second connector terminal T2a, the hook section Fa is caught by a part of the insulating member 1a sealing the body Ha so as to restrict displacement of the fitting section Ka. The hook section Fa is integrally formed with the contact piece section Ka1.

When the first connector terminal T1 is inserted, a predetermined part (a pedestal section Pa) of the insulating member 1a can work as a part restricting displacement of the fitting section Ka. Specifically, when the first connector terminal T1 is inserted, a bottom surface of the fitting section Ka of the second connector terminal T2a shown in FIG. 4A hits the pedestal section Pa shown in FIG. 3, and downward displacement of the fitting section Ka is restricted. When the first connector terminal T1 is pulled out, upward displacement is generated at the fitting section Ka. Thus, if the second connector terminal T2a does not include the hook section Fa shown in FIG. 4A, because there is nothing to restrict upward displacement of the fitting section Ka, upward tensile stress is generated at the arm section Ma and the joint section Sa, the S-shape of the arm section Ma may loose, and the arm section Ma may loose elastic deformability. Thus, it is preferable that the hook section Fa is integrally formed so that an excess stress is not generated at the arm section Ma and the joint section Sa when the first connector terminal T1 is pulled out.

A power supply module 62 according to a first modification of the first embodiment will be described below. The power supply module 62 includes the body Ha same as the body Ha of the power supply module 61. However, second connector terminals T2b bonded to the frames 2a are different from the second connector terminals T2a of the power supply module 61.

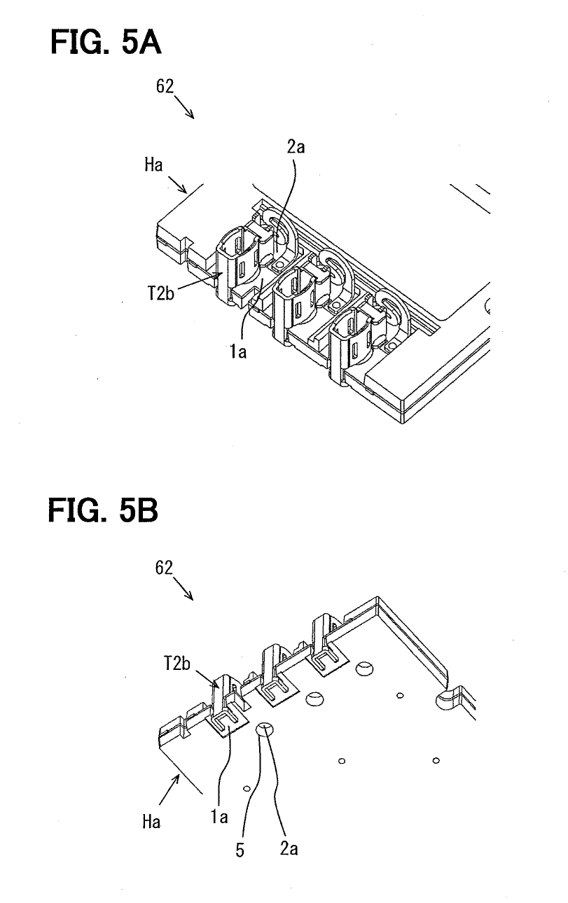

The power supply module 62 supplies power to a load (e.g., the driving motor 10 shown in FIG. 1) and includes the body Ha sealed with the insulating member (molded resin) 1a by transfer molding. The second connector terminals T2b are female terminals fitted with the first connector terminals T1. The second connector terminals T2b are bonded to the frames 2a exposed from the insulating member 1a sealing the body Ha. The frames 2a have first surfaces bonded to the second connector terminals T2b and second surfaces opposite from the first surfaces. The first connector terminals T1 of the load are inserted into the second connector terminals T2b from above in FIG. 5A, and the first connector terminals T1 are fitted with the second connector terminals T2b.

The second connector terminals T2b are bonded to the frames 2a exposed from insulating member 1a by resistance welding. Thus, as shown in FIG. 5B, the insulating member 1a has welding holes 5 to which one electrode for the resistance welding is inserted. The welding holes 5 have the minimum size required for insertion of the electrode. The welding holes 5 expose the second surfaces of the frames 2a from the insulating member 1a.

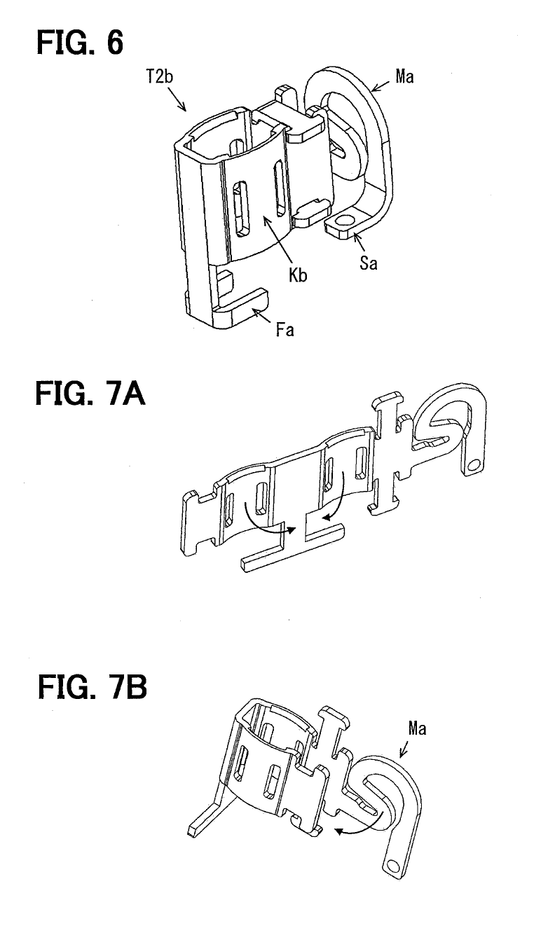

As shown in FIG. 6, the second connector terminal T2b includes the joint section Sa, the arm section Ma, and the hook section Fa same as the joint section Sa, the arm section Ma, and the hook section Fa in the second connector terminal T2a. The second connector terminal T2b further includes a fitting section Kb, which is different from the fitting section Ka of the second connector terminal T2a.

The fitting section Kb has a fitting structure of two contact beams. Basically, up to approximately half electric current of the four contact beams can flow in the two contact beams. In the second connector terminal T2b, when the length of the fitting section Kb coming into contact with the first connector terminal T1 is increased, the contact resistance can be reduced, and flowing current can be increased.

In the second connector terminal T2b, the joint section Sa, the fitting section Kb, the arm section Ma, and the hook section Fa are integrally formed by bending process. Thus, the second connector terminal T2b can be manufactured at a lower cost than the second connector terminal T2a.

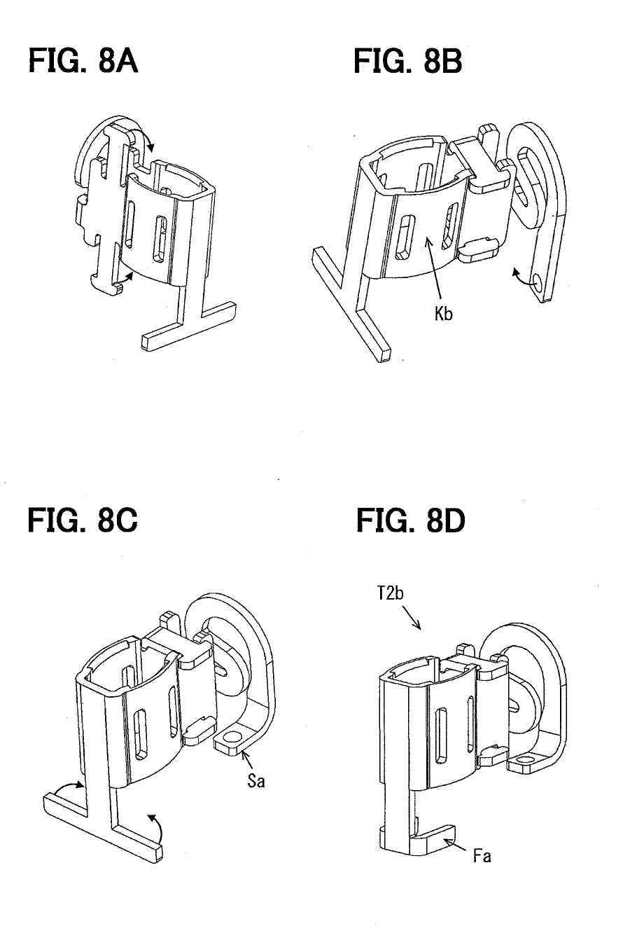

A method of manufacturing the second connector terminal T2b will be described with reference to FIG. 7A, FIG. 7B and FIG. 8A to FIG. 8D.

Firstly, a base member of the second connector terminal T2b is punch-pressed to a developed shape shown in FIG. 7A. The base member is, for example, a Sn-plated copper alloy plate. The base member is treated with a bending process and the fitting section Kb is primarily formed as shown in FIG. 7B.

The arm section Ma is bent at 90 degrees in a direction shown by the arrow in FIG. 7B, and the arm section Ma is formed as shown in FIG. 8A, in which the base member is viewed from a different direction from FIG. 7B.

Next, a part of the base member is bent in a direction shown by the arrow in FIG. 8A to finally form the fitting section Kb as shown in FIG. 88.

Then, a part of the base member is bent at 90 degrees in a direction shown by the arrow in FIG. 88 to form the joint section Sa as shown in FIG. 8C.

Next, a part of the base member is bent in a direction shown by the arrow in FIG. 8C to form the hook section Fa as shown in FIG. 8D.

Accordingly, the second connector terminal T2b is manufactured.

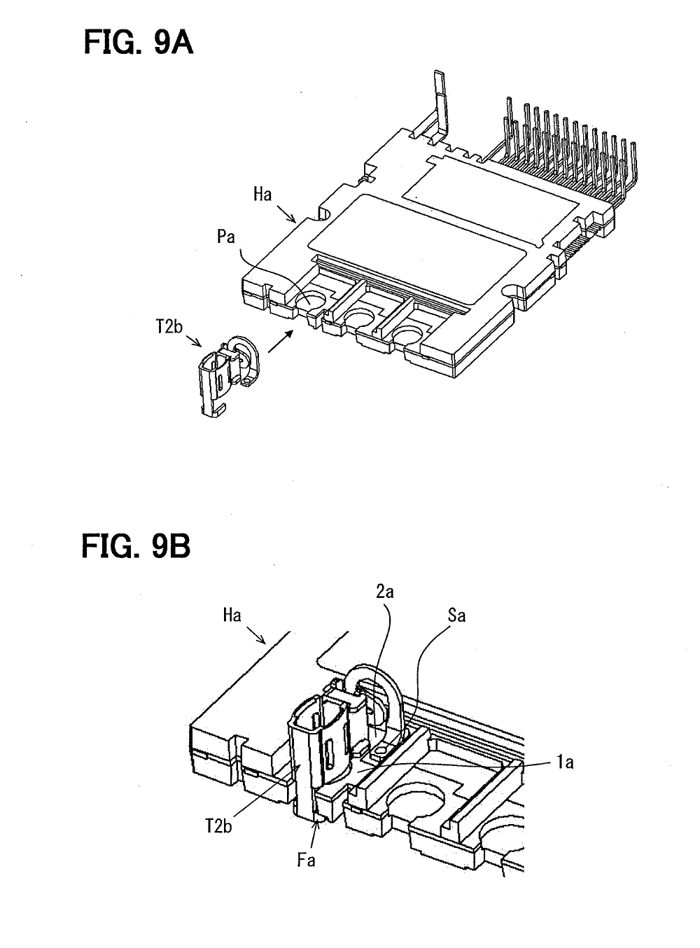

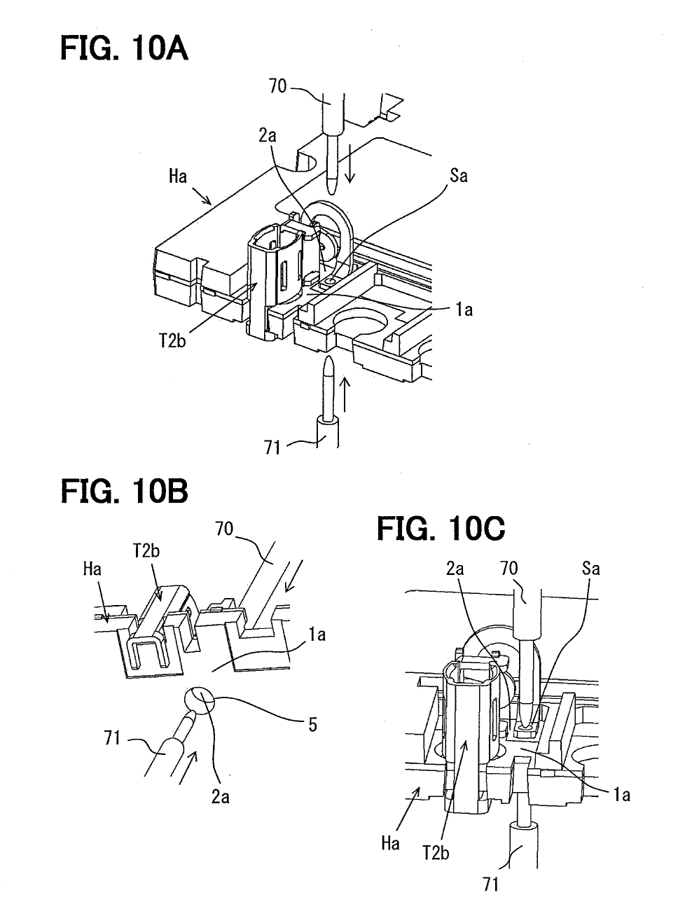

A method of welding the second connector terminal R2b to the body Ha will be described with reference to FIG. 9A, FIG. 9B and FIG. 10A to FIG. 10C.

Firstly, as shown in FIG. 9A, the second connector terminal T2b is inserted into the body Ha in a direction shown by the arrow and is set on the pedestal section Pa.

FIG. 98 is a diagram showing a state where the second connector terminal T2b is set on the pedestal Pa. In this state, the second connector terminal T2b is arranged such that the hook section Fa is caught by a part of the insulating member 1a sealing the body Ha and the joint section Sa is located above the frame 2a exposed from the insulating member 1a.

Then, the second connector terminal T2b is treated with a resistance welding process as shown in FIG. 10A to FIG. 10C.

As shown in FIG. 10A, one welding electrode 70 is set such that an end of the welding electrode 70 presses the projection formed in the joint section Sa of the second connector T2b. Another welding electrode 71 is set such that an end of the welding electrode 71 presses a rear surface of the frame 2a exposed through the welding hole 5 defined on a rear surface of the body Ha. Then, as shown in FIG. 10C, the joint section Sa and the frame 2a are sandwiched by the welding electrodes 70, 71, and a large current is applied to a contact portion of a surface of the frame 2a and the joint section Sa as a welding joint portion. Accordingly, the contact portion is welded by resistance heat generated at the contact portion, and the frame 2a and the second connector terminal T2b are welded.

In the power supply modules according to the present disclosure, it is preferable that the second connector terminal is bonded to the frame exposed from the insulating member by resistance welding which provides a high joint strength in a short time. However, the second connector terminal may be bonded to the frame by another method, such as soldering.

In a case where second connector terminal T2b is bonded to the frame 2a by resistance welding, as shown in FIG. 10B, the welding hole 5, which exposes the second surface of the frame 2a, is integrally formed in the insulating member 1a. Accordingly, an area of the frame 2a exposed from the insulating member 1a can be the minimum. However, the frame 2a may be exposed from the body Ha in another way so that the welding electrodes 70, 71 can be set easily.

Next, power supply modules according to various modifications of the first embodiment will be described.

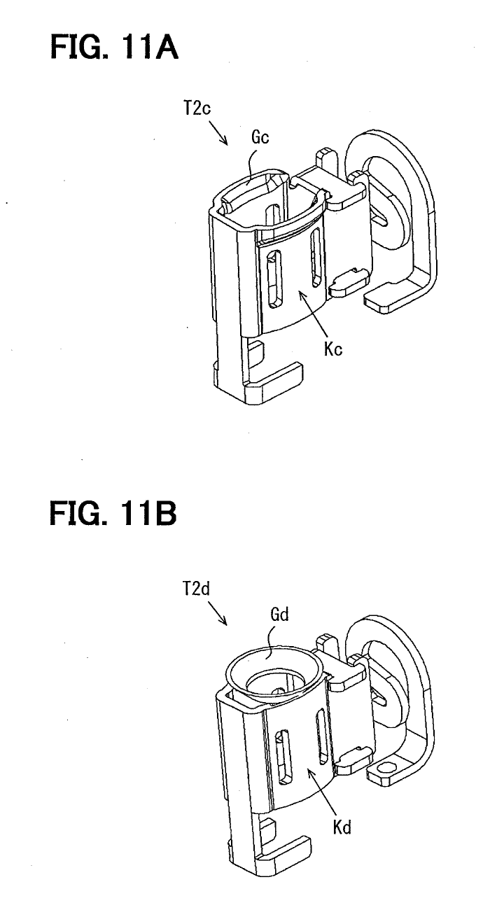

A second connector terminal T2c according to a second modification of the first embodiment and a second connector terminal T2d according to a third modification of the first embodiment will be described with reference to FIG. 11A and FIG. 11B.

As shown in FIG. 11A, the second connector terminal T2c includes a fitting section Kc similar to the fitting section Kb and a guide Gc having a taper shape. The guide Gc is integrally formed with the fitting section Kc at an end of the fitting section Kc from which the first connector terminal T1 is inserted. The guide Gc can facilitate insertion of the first connector terminal T1 and can lead the first connector terminal T1 to a fitting position.

As shown in FIG. 11B, the second connector terminal T2d includes a fitting section Kd similar to the fitting section Kb and a guide Gd having a taper shape. The guide Gd is separately formed from the fitting section Kd and is attached on an end of the fitting section Kd from which the first connector terminal T1 is inserted. The guide Gd can facilitate insertion of the first connector terminal T1 and can lead the first connector terminal T1 to a fitting position.

As described above, in a case where the first connector terminal of the load is the male terminal and the second connector terminal fitted with the first connector terminal is the female terminal, the guide having a taper shape may be disposed on an end of the second connector terminal from which the first connector terminal is inserted so as to facilitate insertion of the first connector terminal.

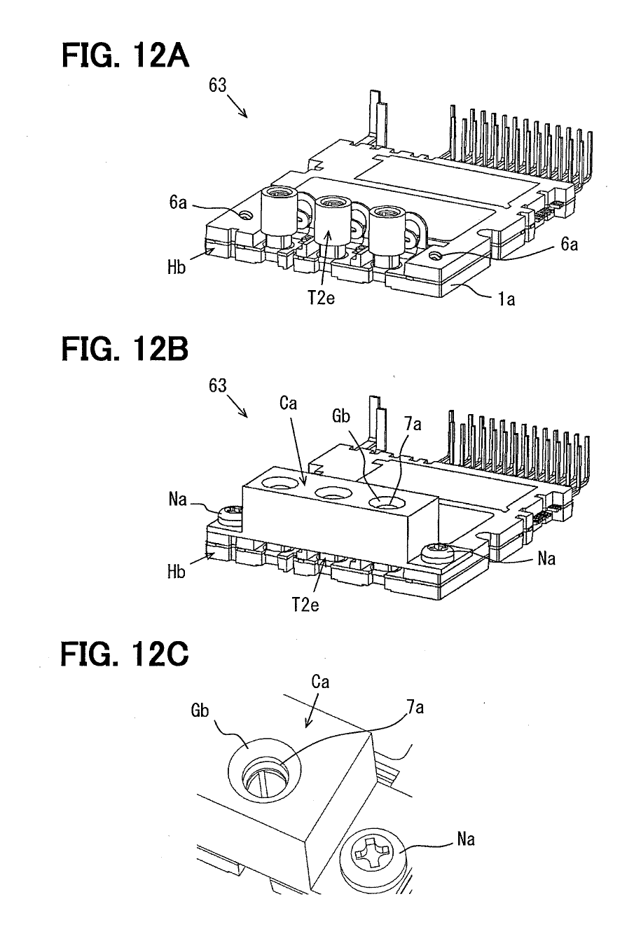

A power supply module 63 according to a fourth modification of the present disclosure will be described with reference to FIG. 12A to FIG. 12C.

The power supply module 63 includes a body Hb similar to the body Ha of the power supply module 61 shown in FIG. 2. However, the insulating member 1a sealing the whole of the body Hb has screw holes 6a for attaching a terminal cover Ca. The power supply module 63 includes second connector terminals T2e. The second connector terminal T2e does not include a hook section Fa differently from the second connector terminal T2a of the power supply module 61.

As shown in FIG. 12B, the terminal cover Ca covers joint sections, fitting sections, and arm sections of the second connector terminals T2e and is fixed to the insulating member 1a with screws Na. The terminal cover Ca is used on request of, for example, insulation. When the first connector terminals T1 are pulled out, the terminal cover Ca limits upward displacement of the fitting sections. Thus, the even through the second connector terminals T2e do not include the hook section Fa, the first connector terminals T1 can be smoothly pulled out.

As shown in FIG. 12C, the terminal cover Ca has insertion holes 7a into which the first connector terminals T1 are inserted. At upper ends of the insertion holes 7a, guides Gb having taper shapes are disposed to facilitate insertion of the first connector terminals T1 into the second connector terminals T2e.

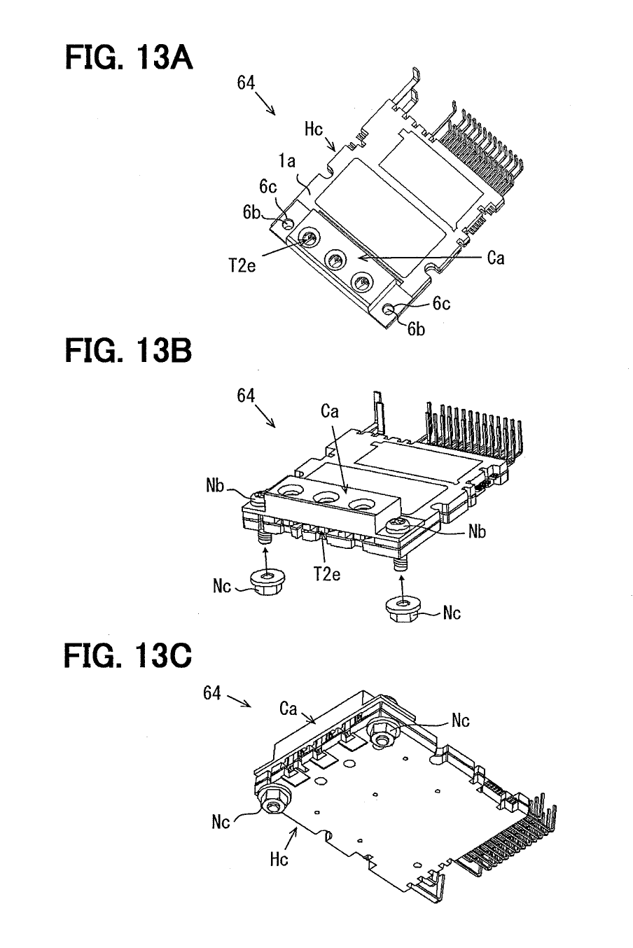

A power supply module according to fifth modification of the first embodiment will be described with reference to FIG. 13A to FIG. 13C. In the power supply module 64, the terminal cover Ca is fixed to a body He with screws Nb and nuts Nc.

As shown in FIG. 13A, the insulating member 1a sealing the body Hc has through holes 6b. The terminal cover Ca has through holes 6c coaxial with the through holes 6b. As shown in FIG. 13B, the screws Nb are inserted into the through holes 6b, 6c. Then, as shown in FIG. 13C, the screws Nb are fixed with the nuts Nc disposed on the rear side of the body Hc. The nuts Nc may be replaced by a metal plate having tapped holes.

As described above, in a power supply module that includes a second connector terminal including a joint section, a fitting section, and a arm section, such as the power supply modules 63, 64, a terminal cover that covers the joint section, the fitting section, and the arm section may be fixed with screws to an insulating member sealing a body of the power supply module so as to restrict a careless contact to the second connector terminal.

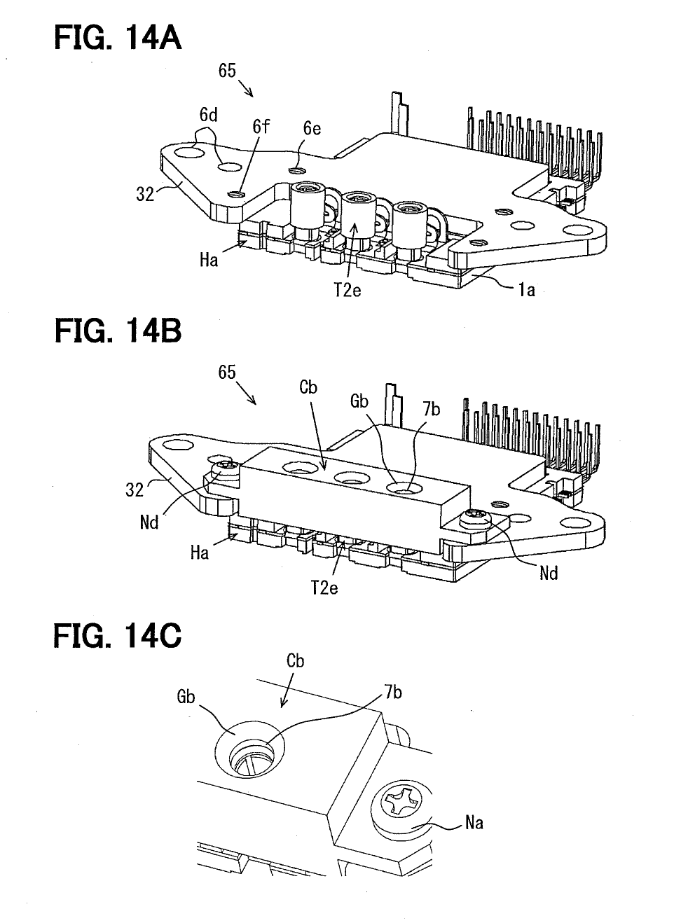

A power supply module 65 according a sixth modification of the first embodiment will be described with reference to FIG. 14A to FIG. 14C. The power supply module 65 includes a terminal cover Cb.

As shown in FIG. 14A, before the terminal cover Cb is attached to the body Ha, a heat radiation member 32 is attached to the body Ha.

In the power supply module 65, the terminal cover Cb that covers the joint sections, the fitting sections, and the arm sections of the second connector terminal T2e is fixed to the heat radiation member 32 with screws Nd.

The heat radiation member 32 has holes 6d, screw holes 6e, and screw holes 6f. The holes 6d are used for assembling the heat radiation member 32 to the cover 11d. The screw holes 6e are used for attaching the heat radiation member 32 to the body Ha. The screw holes 6f are used for attaching the terminal cover Cb to the heat radiation member 32 with the screws Nd.

As shown in FIG. 14C, the terminal cover Cb has insertion holes 7b into which the first connector terminals T1 are inserted. At upper ends of the insertion holes 7a, guides Gb having taper shapes are disposed so as to facilitate insertion of the first connector terminals T1 into the second connector terminals T2e.

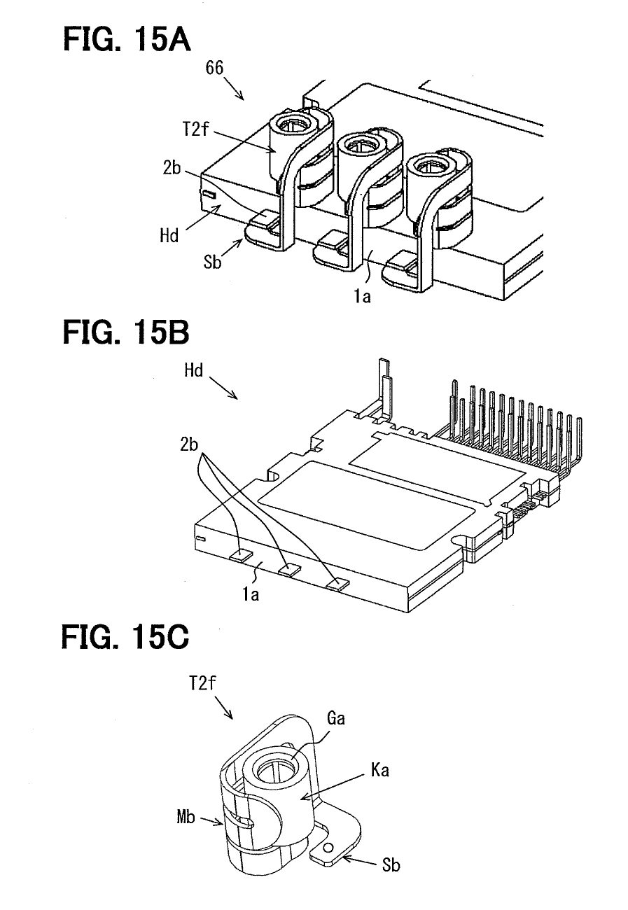

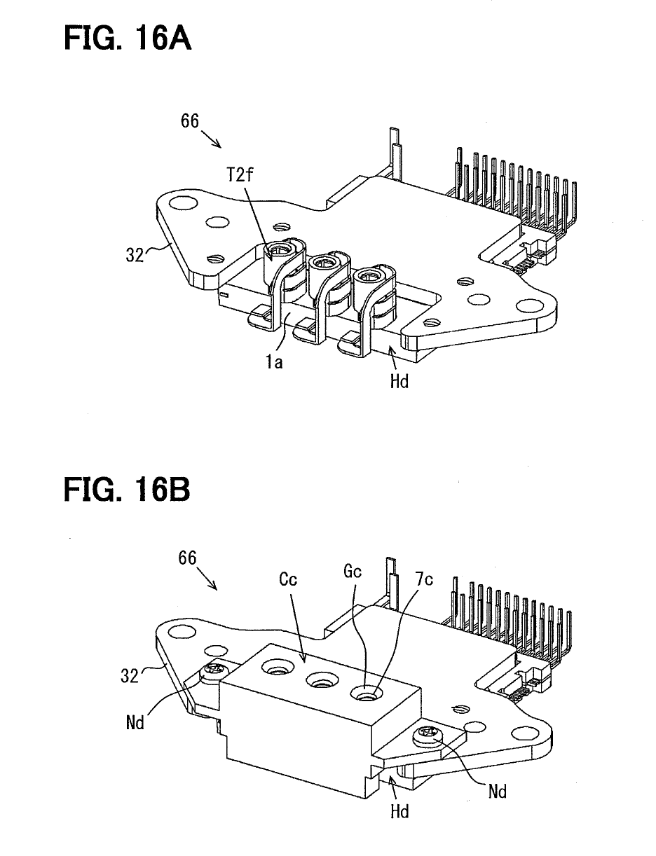

A power supply module 66 according to a seventh modification of the first embodiment will be described with reference to FIG. 15A to FIG. 15C, FIG. 16A, and FIG. 16B.

The power supply module 66 has a configuration in which second connector terminals T2f can be welded more easily than the above-described power supply modules 61-65.

In the above-described power supply modules 61-65, the frames 2a bonded to the second connector terminals T2a-T2e are exposed from the insulating member 1a in a state where the frames 2a are depressed from the insulating member 1a. In the power supply module 66, frames 2b protrude from a side surface of the insulating member 1a sealing a body Hd so that the second connector terminals T2f can be easily bonded to the frames 2b.

As shown in FIG. 15C, the second connector terminal T2f includes a joint section Sb, a fitting section Ka, and an arm section Mb. The fitting section Ka has the same configuration as the fitting section Ka in the second connector terminal T2a shown in FIG. 4A. The joint section Sb has a projection.

As shown in FIG. 15A, in a state where the second connector terminals T2f are arranged on the body Hd, the frames 2b protruding from the insulating member 1a and the joint sections Sb of the second connector terminals T2f are sandwiched by welding electrodes from above and below. Then, a large current is applied between the welding electrodes to weld the frames 2b and the joint sections Sb of the second connector terminals T2f.

Then, as shown in FIG. 16A and FIG. 16B, a terminal cover Cc is attached to the heat radiation member 32 with the screws Nd. The terminal cover Cc has insertion holes 7c in which the first connector terminals T1 are inserted, and guides Gb having taper shapes are disposed at upper ends of the insertion holes 7c so as to facilitate insertion of the first connector terminals T1 into the second connector terminals T2f.

As shown in FIG. 15A, when the first connector terminals 1 are inserted, the upper surface of the insulating member 1a, which seals the body Hd, restricts downward displacement of the fitting sections Ka of the second connector terminals T2f. On the other hand, when the first connector terminals T1 are pulled out, the terminal cover Cc shown in FIG. 16B restricts upward displacement of the fitting sections Ka of the second connector terminals T2f. The upward displacement of the fitting sections Ka of the second connector terminals T2f at a time when the first connector terminals T1 are pulled out may also be restricted by hook sections which are integrally formed with the fitting section Ka in a manner similar to the second connector terminals T2a shown in FIG. 4A.

As described above, in the power supply module 66, the second connector terminals T2f and the terminal cover Cc protrude to a side on which the heat radiation member 32 is attached. A stress is applied to the body Hd when the first connector terminals T1 are inserted, and a stress is applied to the terminal cover Cc when the first connector terminals T1 are pulled out.

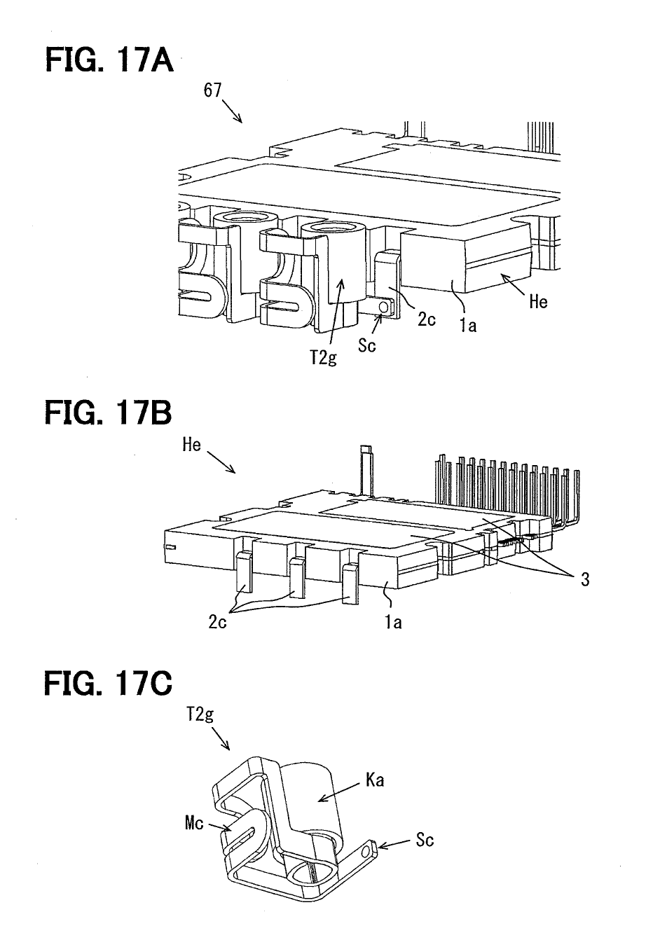

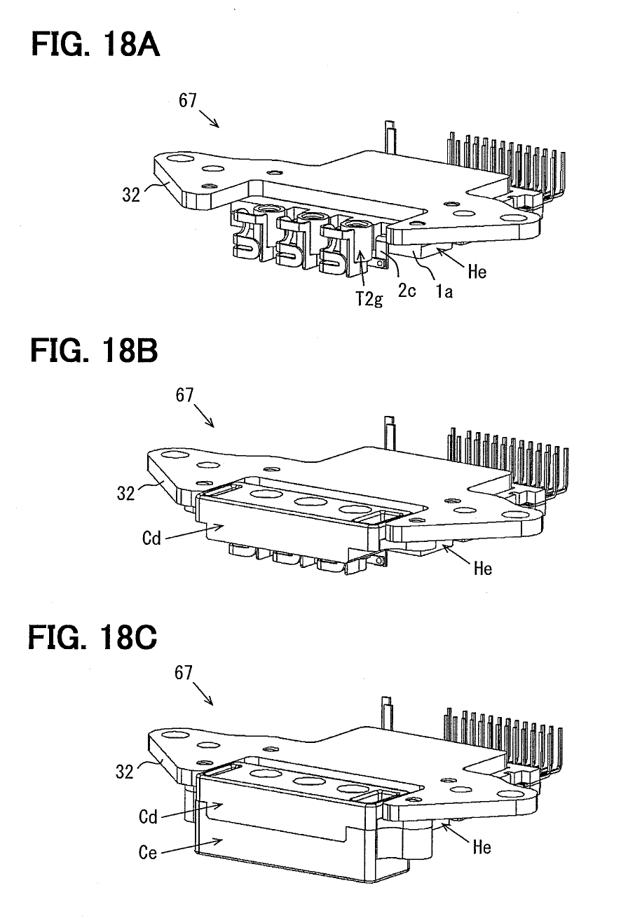

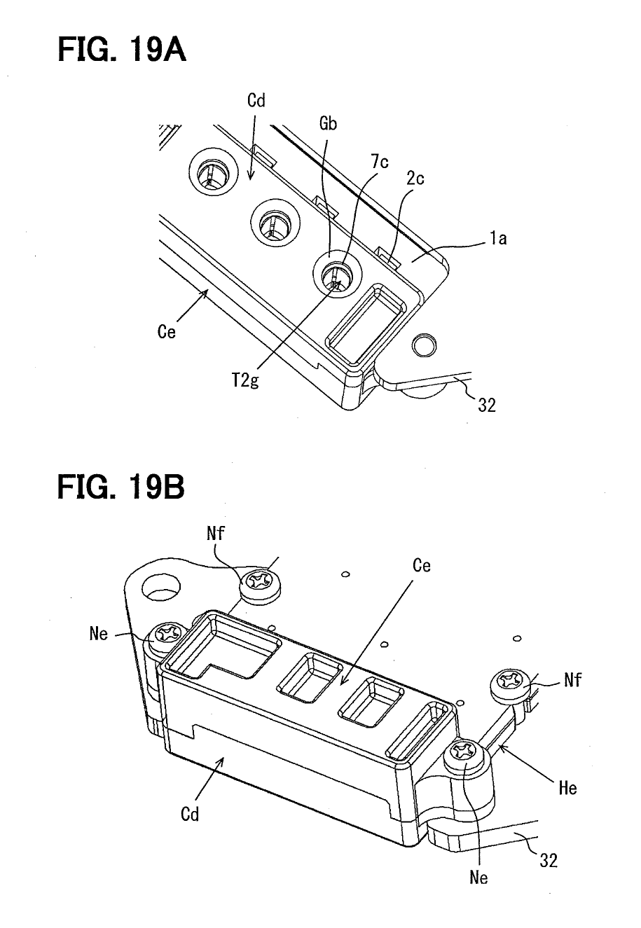

Next, a power supply module 67 according to an eighth modification of the first embodiment will be described with reference to FIG. 17A to FIG. 17C, FIG. 18A to FIG. 18C, FIG. 19A and FIG. 19B. The power supply module 67 can be used even in a case where a projection of the second connector terminals to a side on which the heat radiation member 32 is attached is not permitted or a case where a stress to the body of the power supply module is not permitted.

As shown in FIG. 17A, in the power supply module 67, second connector terminals T2g are bonded to frames 2c exposed from the insulating member 1a that seals a body He. As shown in FIG. 17B, the frames 2c have approximately rectangular shapes protruding from the insulating member 1a. The frames 2c are bent at root portions in a direction opposite from the heat radiation surface 3 and protrude downward from the insulating member 1a defining a bottom of the body He.

As shown in FIG. 17C, the second connector terminal T2g includes a joint section Sc, a fitting section Ka, and an arm section Mc. The fitting section Ka has the same configuration as the fitting section Ka in the second connector terminal T2a shown in FIG. 4A. The joint section Sc has a projection.

In a state where the second connector terminals T2f are arranged with respect to the body He as shown in FIG. 17A, the joint sections Sc of the second connector terminals T2g and the frames 2c protruding from the insulating member 1a are sandwiched by welding electrodes from front and behind. Then, a large current is applied between the welding electrodes to weld the frames 2b and the joint sections Sc of the second connector terminals T2f.

In the power supply module 67, a first terminal cover Cd and a second terminal cover Ce are attached to the heat radiation member 32 with screws Ne shown in FIG. 19B. The body He and the heat radiation member 32 are fixed with screws Nf.

The first terminal cover Cd and the second terminal cover Ce need to restrict displacement of the fitting sections Ka of the second connector terminals T2g when the first connector terminals T1 are inserted or pulled out. After the heat radiation member 32 is attached to the body He as shown in FIG. 18A, the first terminal cover Cd shown in FIG. 18B and the second terminal cover Ce shown in FIG. 18C are attached. As shown in FIG. 19A, the terminal cover Cd has insertion holes 7d in which the first connector terminals T1 are inserted. Guides Gb having taper shapes are disposed at upper ends of the insertion holes 7d so as to facilitate insertion of the first connector terminals T1 into the second connector terminals T2g.

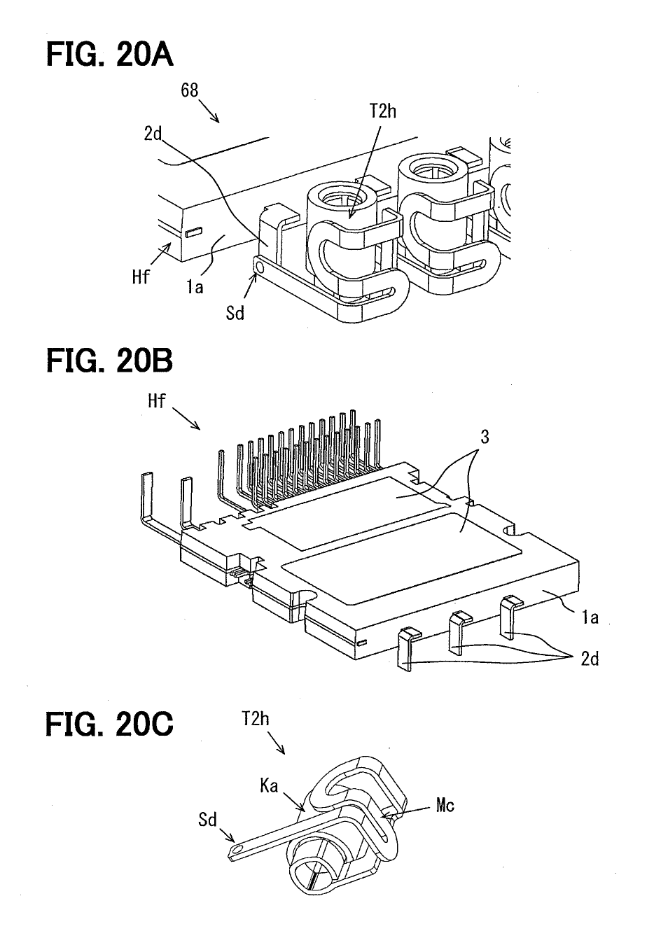

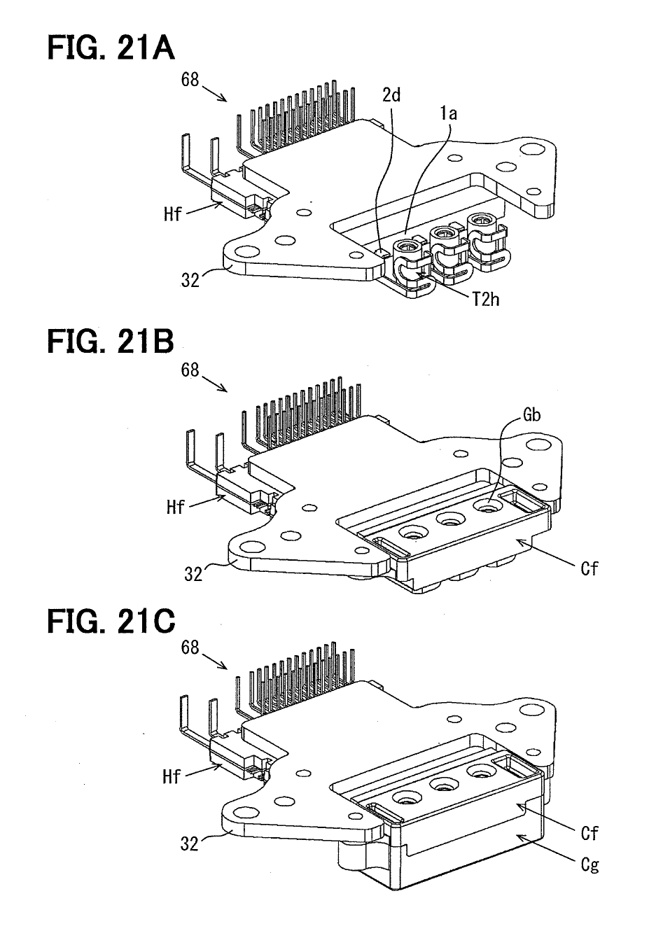

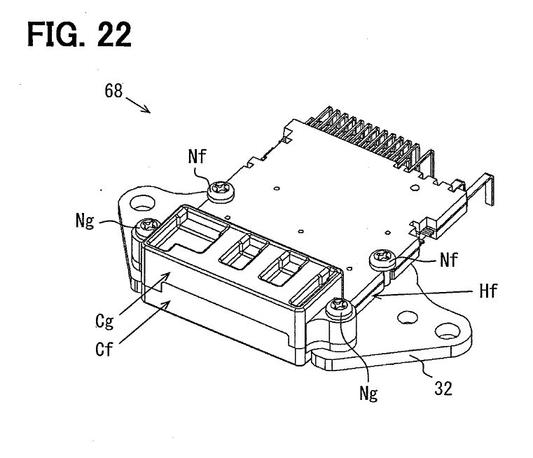

Next, a power supply module 68 according to a ninth modification of the first embodiment will be described with reference to FIG. 20A to FIG. 20C, FIG. 21A to FIG. 21C, and FIG. 22.

As shown in FIG. 20A, in the power supply module 68, second connector terminals T2h are bonded to frames 2d exposed from the insulating member 1a that seals a body Hf. The frames 2d have L-shapes. The frames 2d are bent at root portions of end side of the L-shapes in a direction opposite from the heat radiation surface 3 and protrude downward from the insulating member 1a defining a bottom of the body Hf.

As shown in FIG. 20C, the second connector terminal T2h includes a joint section Sd, a fitting section Ka, and an arm section Mc. The fitting section Ka and the arm section Mc have the same configurations as the fitting section Ka and the arm section Mc in the second connector terminal T2g shown in FIG. 17C.

In a state where the second connector terminals T2h are arranged with respect to the body Hf as shown in FIG. 20A, the joint sections Sd of the second connector terminals T2h and the frames 2d protruding from the insulating member 1a are sandwiched by welding electrodes from right and left. Then, a large current is applied between the welding electrodes to weld the frames 2d and the joint sections Sd of the second connector terminals T2g.

Also in the power supply module 68, a first terminal cover Cf and a second terminal cover Cg need to restrict displacement of the fitting sections Ka of the second connector terminals T2h when the first connector terminals T1 are inserted or pulled out. After the heat radiation member 32 is attached to the body He as shown in FIG. 21A, the first terminal cover Cf shown in FIG. 21B and the second terminal cover Cg shown in FIG. 21C are attached. Then, as shown in FIG. 22, the first terminal cover Cf and the second terminal cover Cg are fixed to the heat radiation member 32 with screws Ng.

In each of the above-described power supply modules 60-68, the second connector terminals T2, T2a-T2h bonded to the frames 2a-2d are female terminals. Because the second connector terminals are attached to the body of the power supply module sealed with the insulating member and are disposed outside the insulating member, a degree of freedom of the shape of the second connector terminals is high. Therefore, the second connector terminals may be the female terminals in a case where the first connector terminals are the male terminals. In a case where the first connector terminals are female terminals, second connector terminals may be male terminals and may be bonded to the frames.

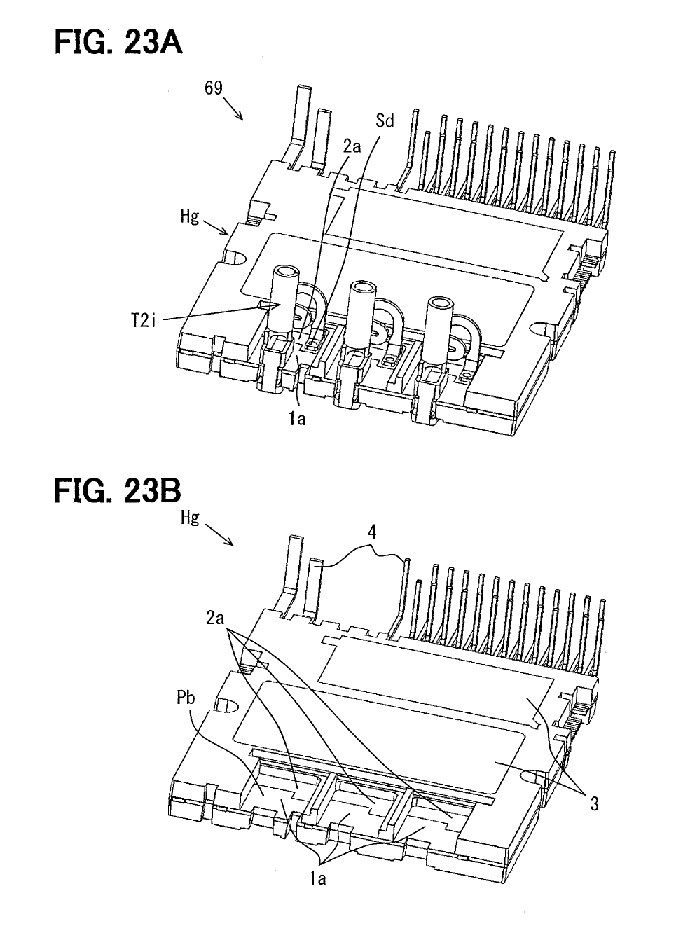

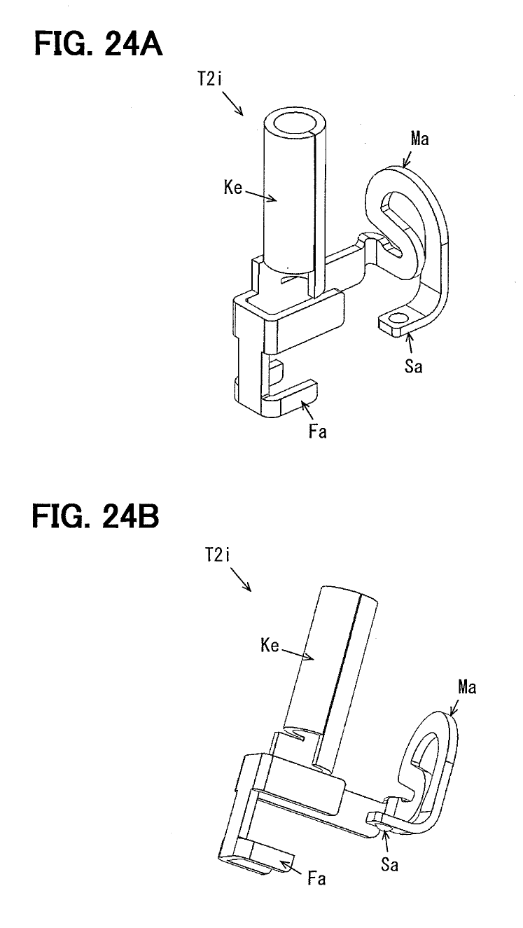

A power supply module 69 according to a tenth modification of the first embodiment will be described with reference to FIG. 23A, FIG. 23B, FIG. 24A, and FIG. 24B.

The power supply module 69 shown in FIG. 23A includes second connector terminals T2i. The second connector terminals T2i are male terminals fitted with first connector terminals of a load which are female terminals. The second connector terminals T2i are bonded to frames 2a exposed from an insulating member 1a sealing a body Hg.

The body Hg of the power supply module 69 shown in FIG. 23B has a configuration similar to the body Ha of the power supply modules 61, 62 on which the second connector terminals T2a, T2b are mounted. However, a shape of pedestal sections Pb on which the second connector terminals T2i are disposed are slightly different of the shape of the pedestal sections Pa.

As shown in FIG. 24A and FIG. 24B, the second connector terminal T2i includes a joint section Sa, a fitting section Ke, an arm section Ma, and a hook section Fa. Except for the fitting section Ke, the second connector terminal T2i has the same configuration as the second connector terminals T2a, T2b. The fitting section K2 is integrally formed with the joint section Sa, the arm section Ma, and the hook section Fa and is formed into a cylindrical shape by a bending process. An outer surface of the fitting section Ke having the cylindrical shape is fitted in the first connector terminal of the load, which is the female terminal. Instead of the fitting section Ke having the cylindrical shape, a fitting section having a column shape may be separately provided.

As described above, each of the power supply modules 60-69 according to the present embodiment includes the body Ha-Hg sealed with the insulating member 1a and can be connected with an arbitrary load without via a printed circuit board.

Thus, each of the power supply modules 60-69 can be suitably used for an electric compressor having an electromechanical integral structure in which a load is the driving motor 10 of the electric compressor disposed in a vehicle, and each of the power supply modules 60-69 is an inverter module that supplies power to the driving motor 10.

When each of the power supply modules 60-69 is used, because a printed circuit board does not exist on a power supply line from the power supply module, solder connection points on a conventional power supply line via a printed circuit board and a connector can be emitted, and the size of the printed circuit board can be reduced.

In each of the power supply modules 60-69, the insulating member 1a sealing the body Ha-Hg is a molded resin formed by transfer molding. As an insulating member sealing a power supply module, molded resin formed by transfer molding is widely used. However, power supply modules according to the present embodiment are not limited to power supply modules sealed with a molded resin by transfer molding and may be a power supply module sealed with a ceramic package or a power supply module sealed with resin by potting.

### Second Embodiment

A power supply module according to a second embodiment of the present disclosure will be described below.

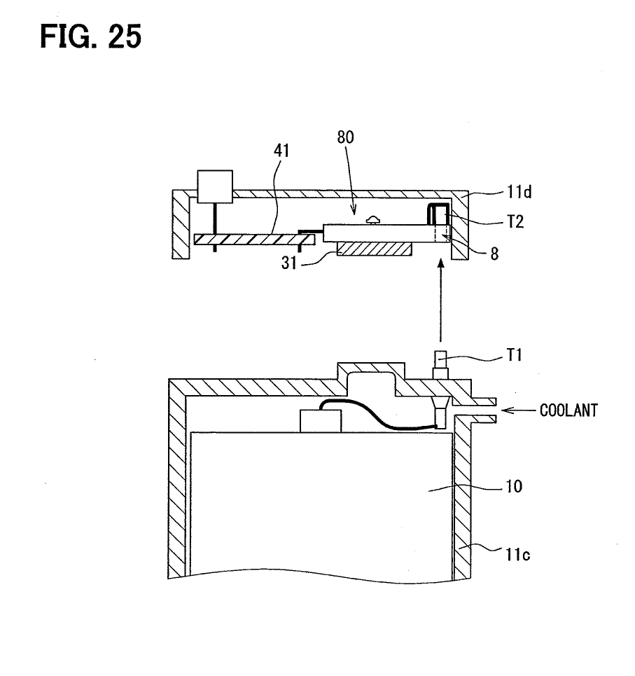

FIG. 25 is a diagram showing a usage example of a power supply module 80 according to the second embodiment. The power supply module 80 can be used as an inverter module that supplies power to an electric compressor having an electromechanical integral structure. The power supply module 80 is assembled to a cover 11d disposed on a housing 11c of a driving motor 10 and supplies power to the driving motor 10 as a load. In the configuration in FIG. 25, components similar to the components shown in FIG. 38 are denoted by the same reference numerals.

In the electric compressor in FIG. 25, the three-phase driving motor 10 driving a compressor is sealed in the housing 11c in which a coolant circulates. Thus, the driving motor 10 is supplied with power via three first connector terminals T1 that penetrate the housing 11c and are sealed air-tightly. As shown in FIG. 25, the first connector terminals T1 are generally cylindrical male terminals.

The power supply module 80 includes a body sealed with an insulating member. The insulating member has through holes 8 in which the first connector terminals T1 are inserted. The power supply module 80 further includes second connector terminals T2 fitted with the first connector terminals T1. The second connector terminals T2 are bonded to frames for power supply exposed from the insulating member. When the cover 11d attached with the power supply module 80 is disposed on the housing 11c of the driving motor 10, the first connector terminals T1 are fitted with the second connector terminals T2, and the power supply module 80 is electrically connected with the driving motor 10 as the load. At the same time, a heat radiation member 31 fixed to the power supply module 80 comes into contact with the housing 11c.

The through holes 8 in which the first connector terminals T1 are inserted are provided in the insulating member sealing the body of the power supply module 80. The through holes 8 can have a function of roughly positioning the first connector terminals T1. The second connector terminals T2 are disposed above the through holes 8. Accordingly, the first connector terminals T1 can be easily fitted into the second connector terminals T2. Because the insulating member around the through holes 8 covers the second connector terminals T2, a terminal cover for the second connector terminals T2 is unnecessary. The through holes 8 can be formed when the insulating member is molded. Thus, a cost of the power supply module 80 does not increase drastically.

In addition, in the power supply module 80, the second connector terminals T2 fitted with the first connector terminals T1 are directly bonded to the frames for power supply exposed from the insulating member that seals the power supply module 80, without via a power supply line such as a printed circuit board.

Thus, the power supply module 80 can be electrically connected with the driving motor 10 without via a lead wire or a printed circuit board differently from the structure shown in FIG. 38. Thus, the solder connection points on the power supply line in the printed circuit board 40, which causes the issues when the conventional power supply module 20 is used, can be eliminated. Also in the configuration shown in FIG. 25, a printed circuit board 41 is used. However, the printed circuit board 41 is a small board in which a power source wiring and a communication wiring to the power supply module 80 are formed. The second connector terminals T2 in the power supply module 80 are attached to the body of the power supply module 80 sealed with the insulating member and are disposed outside the insulating member. Thus, a degree of freedom of the shape of the second connector terminals T2 tailored to the first connector terminals T1 is high.

As described above, the power supply module 80 configured to supply power to the load includes the body sealed with the insulating member and restricts displacement from the appropriate fitting position due to assembling error of the first connector terminals T1 of the load and the second connector terminals T2 of the power supply module 80. In addition, the power supply module 80 can be electrically connected with the load directly via the second connector terminals T2 and can be manufactured at a low cost.

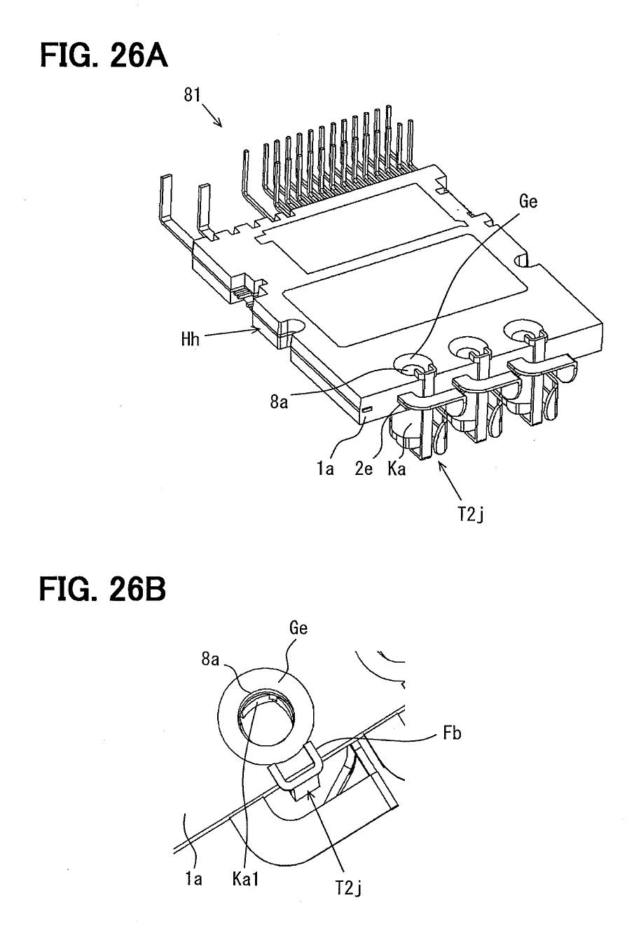

Next, a configuration of a power supply module 81 as a concrete example of the power supply module 80 will be described with reference to FIG. 26A to FIG. 29B.

The power supply module 81 shown in FIG. 26A supplies power to a load (e.g., the driving motor 10 shown in FIG. 25) and includes a body Hh sealed with an insulating member (molded resin) 1a by transfer molding. The insulating member 1a has through holes 8a in which the first connector terminals T1 are inserted. At ends of the through holes 8a from which the first connector terminals T1 are inserted, guides Ge having a taper shape are disposed so as to facilitate insertion of the first connector terminals T1. The body Hh has a first surface on which the guides Ge are disposed and a second surface opposite from the first surface. The power supply module 81 further includes second connector terminals T2j disposed on the second surface of the body Hh. The second connector terminals T2j are female terminals fitted with the first connector terminals T1, which are the male terminals. From a side surface of the body Hh, frames 2e for power supply protrude so as to be exposed from the insulating member 1a. The second connector terminals T2j are bonded to the frames 2e. The first connector terminals T1 are inserted into the through holes 8a of the insulating member 1a from above the first surface of the body Hh, and the first connector terminals T1 and the second connector terminals T2j are fitted with each other below the body Hh.

The through holes 8a can have a function of roughly positioning the first connector terminals T1. The second connector terminals T2j are disposed below the through holes 8a. Thus, the first connector terminals T1 can be easily fitted into the second connector terminals T2j. Because the insulating member 1a around the through holes 8a covers the second connector terminals T2j, a terminal cover for the second connector terminals T2j is unnecessary. The through holes 8a can be formed when the insulating member 1a is molded. Thus, a cost of the power supply module 81 does not increase drastically.

In a case were the guides Ge are disposed at the ends of the through holes 8a, a terminal cover for the second connector terminals T2j is unnecessary. Because the guides Ge can be formed when the insulating member 1a of the power supply module 81 is formed, the cost of the power supply module 81 does not increase drastically.

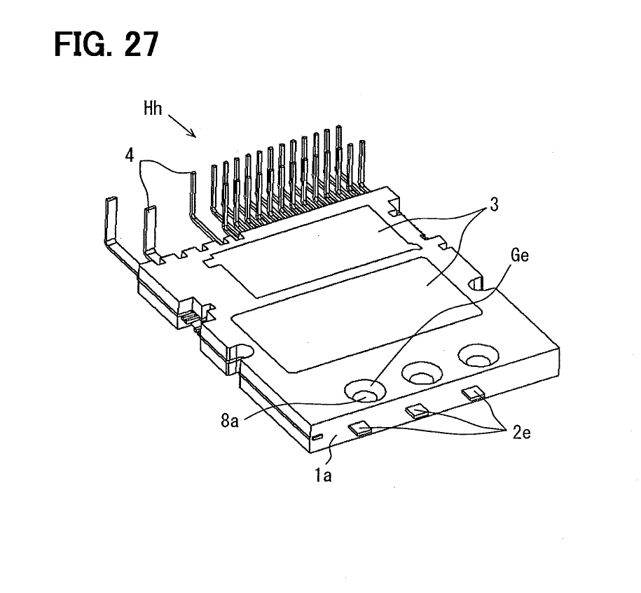

As shown in FIG. 27, the body Hh of the power supply module 81 of the three-phase alternating-current inverter is sealed with the insulating member 1a. Three power supply frames 2e respectively corresponding to output terminals of a U-phase, a V-phase, a W-phase are exposed from the insulating member 1a on the side surface of the body Hh. The frames 2e can function as hanging frames in a transfer molding process of the insulating member 1a.

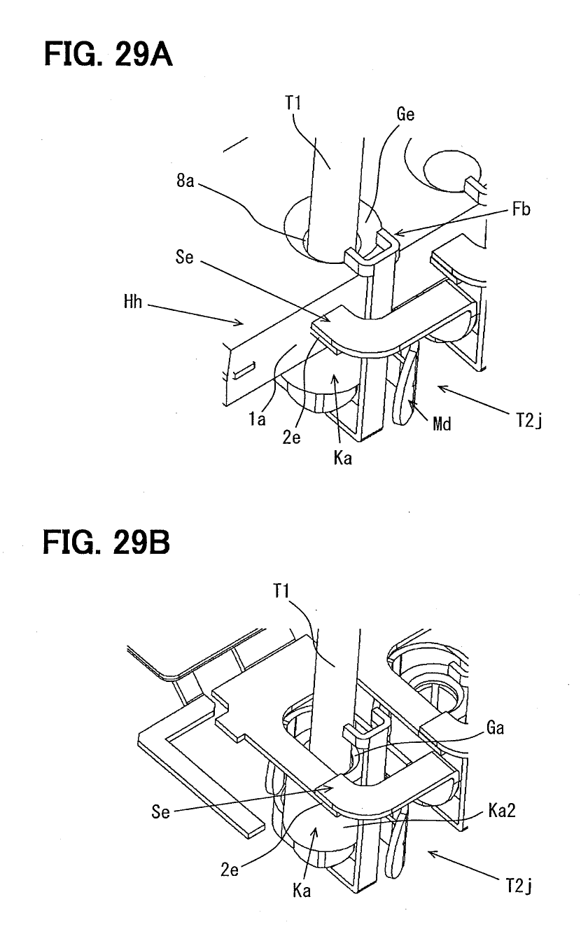

As shown in FIG. 29B, a frame pattern functioning as an internal electric circuit is formed around the through holes 8a so as not to interfere with the first connector terminals T1 inserted into the through holes 8a. Furthermore, a heat radiation plate formed of another frame is buried in the insulating member 1a. A heat radiation surface 3 shown in FIG. 27 comes into contact with the heat radiation member 31 fixed to the first surface of the body Hh. Lead frames 4 for power supply and control are bent into L-shapes and are connected to the printed circuit board 41 shown in FIG. 25.

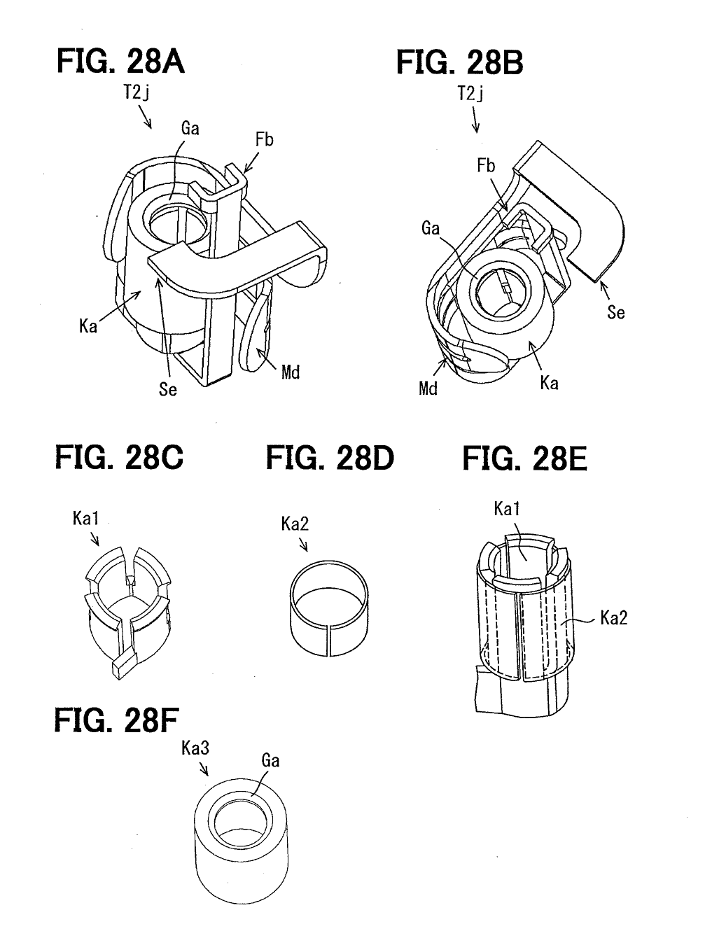

As shown in FIG. 28A and FIG. 28B, the second connector terminal T2j includes a joint section Se, a fitting section Ka, an arm section Md, and a hook section Fb. The joint section Se is bonded to the frame 2e for power supply. The fitting section Ka is fitted with the first connector terminal T1 of the load. The arm section Md connects the joint section Se and the fitting section Ka. A current path of the second connecter terminal T2j to the load passes from the joint section Se to the fitting section Ka via the arm section Md.

The joint section Se is bonded to the frame 2a exposed from the insulating member 1a sealing the body Ha. The frame 2e and the joint section Se of the second connector terminal T2j are bonded by resistance welding. In a case where a projection welding is performed, a projection for the projection welding is formed at the joint section Se.

The fitting section Ka is a female terminal fitted with the first connector terminal T1. The fitting section Ka includes a contact piece section Ka1 shown in FIG. 28C and a cylindrical spring section Ka2 shown in FIG. 28D. The contact piece section Ka1 includes four pieces connected at a bottom portion and has a ring shape. The cylindrical spring section Ka2 has a cylindrical shape and has a spring property. The contact piece section Ka1 is covered with the cylindrical spring section Ka2. The contact piece section Ka1 is integrally formed with the arm section Md, the joint section Se, and the hook section Fb from one plate by punching press and is formed into a ring shape by a bending process. The contact piece section Ka1 has a protruding portion that protrudes from the bottom portion connecting the four pieces. The protruding portion is connected with the arm section Md. The contact piece section Ka1 is covered with the cylindrical spring section Ka2 as shown in FIG. 28E. In addition, the contact piece section Ka1 and the cylindrical spring section Ka2, which are assembled as shown in FIG. 28E, is covered with a cylindrical guide section Ka3 shown in FIG. 28F. Accordingly, the fitting section Ka is assembled as shown in FIG. 28A and FIG. 28B. The cylindrical guide section Ka3 has a guide Ga having a taper shape at an end from which the first connector terminal T1 is inserted. The guide Ga facilitates insertion of the first connector terminal T1 and leads the first connector terminal T1 to a fitting position. The guide Ga finally corrects a gap from the fitting position to which the guide Ge of the body Hh does not sufficiently introduce the first connector terminal T1. When the first connector terminal T1 of the load is inserted into a center of the contact piece section Ka1, a fitting structure having four contact beams is formed. Accordingly, a usable supply current can be increased compared with a case where contact beams are two beams.

The arm section Md is elastically deformable and connects the joint section Se and the fitting section Ka. When the fitting section Ka is fitted with the first connector terminal T1, the arm section Ms corrects a gap between center positions of the fitting section Ka and the first connector terminal T1. Because the first connector terminal T1 is fixed, the position of the fitting section Ka is adjusted with elastic deformation of the arm section Md. Accordingly, the fitting section Ka is fitted smoothly with the first connector terminal T1. Specifically, when the first connector terminal T1 is inserted into the fitting section Ka, displacement generated by the position correction of the fitting section Ka is caused by the elastic deformation of the arm section Md because the joint section Se is fixed by welding. The second connector terminal T2j is designed such that the arm section Md and the hook section Fb deform more easily than the fitting section Ka and a connection reliability and a connection resistance value of the fitting portion Ka are maintained. The shape of the arm section Md depends on the joint section Se bonded to the frame 2e. The arm section Md has an approximately S shape.

In the second connector terminal T2j, because the arm section Md, which is elastically deformable, is provided between the joint section Se and the fitting section Ka, even if there is a positional gap or an angular gap with respect to the first connector terminal T1 when the first connector terminal T1 is fitted into the second connector terminal T2j, the gap can be absorbed by the elastic deformation of the arm section Md. Thus, even if there is a positional gap of an angular gap when the first connector terminal T1 is fitted into the second connector terminal T2j, unexpected stress is not generated at the joint section Se and the fitting section Ka of the second connector terminal T2j, and a stable electrical connection can be maintained.

When the first connector terminal T1 is inserted into the second connector terminal T2j as shown in FIG. 29A, the hook section Fb is caught by a part of the insulating member 1a sealing the body Hh so as to restrict displacement of the fitting section Ka. The hook section Fb is integrally formed with the contact piece section Ka1.

When the first connector terminal T1 is pulled out, a predetermined part of a lower surface of the insulating member 1a sealing the body Hh can function as a portion restricting displacement of the fitting section Ka. When the first connector terminal T1 is pulled out, an upper surface of the fitting section Ka of the second connector terminal T2j hits lower surface of the insulating member, and upward displacement of the fitting section Ka is restricted. When the first connector terminal T1 is inserted, downward displacement is generated at the fitting section Ka. Thus, if the second connector terminal T2a does not include the hook section Fb shown in FIG. 28A and FIG. 28B, because there is nothing to restrict downward displacement of the fitting section Ka, downward tensile stress is generated at the arm section Md and the joint section Se, the S-shape of the arm section may Md loose, and the arm section Md may loose elastic deformability. Thus, it is preferable that the hook section Fb is formed by integral forming so that an excess stress is not generated at the arm section Md and the joint section Se when the first connector terminal T1 is inserted.

Next, a power supply module 82 according to a first modification of the second embodiment will be described below.

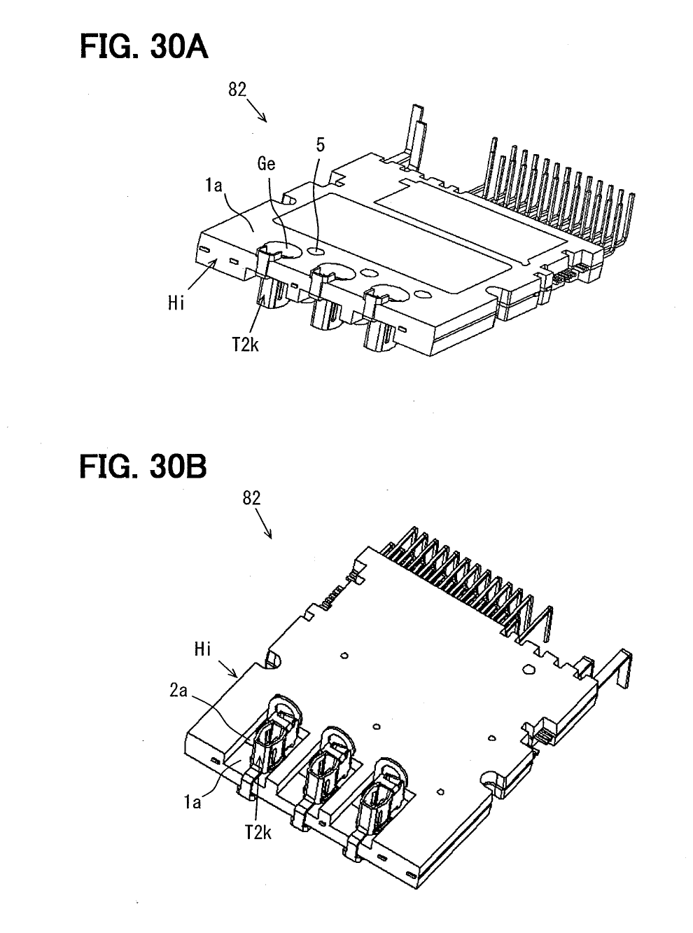

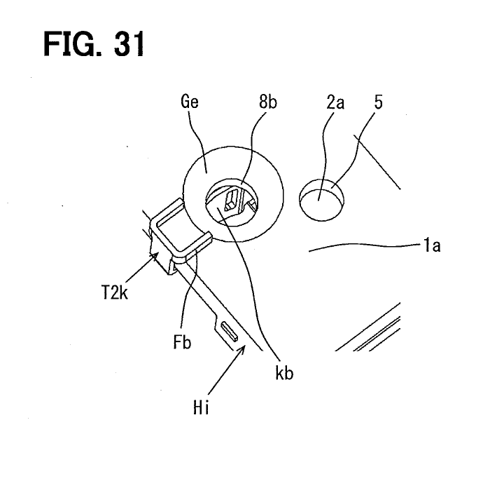

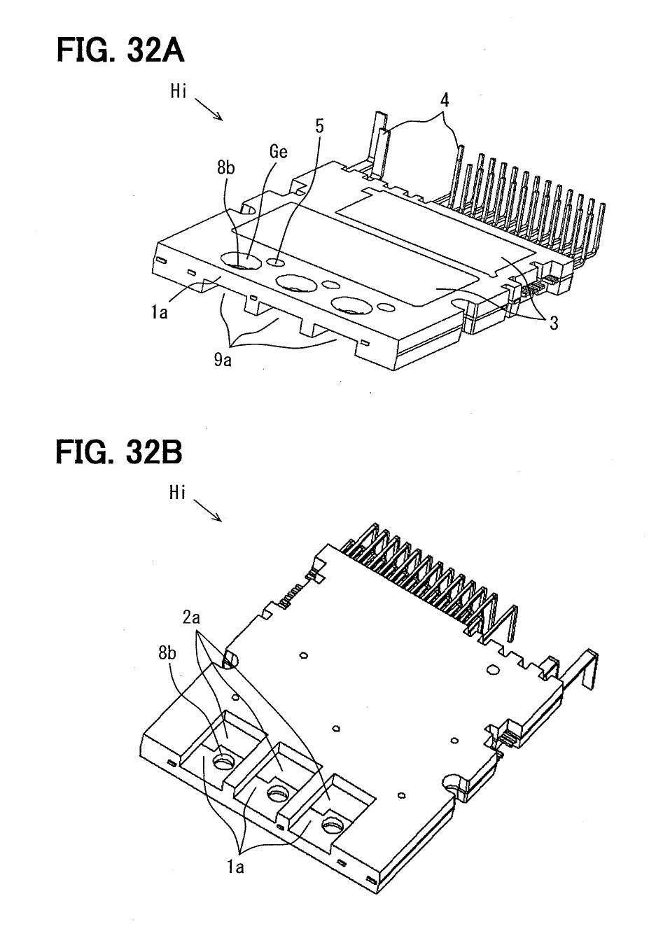

The power supply module 82 shown in FIG. 30A and FIG. 30B supplies power to a load (e.g., the driving motor 10 shown in FIG. 25) and includes a body Hi sealed with an insulating member (molded resin) 1a by transfer molding. As shown in FIG. 31, FIG. 32A and FIG. 328, the insulating member 1a has through holes 8b in which the first connector terminals T1 are inserted. At ends of the through holes 8b from which the first connector terminals T1 are inserted, guides Ge having a taper shape are disposed so as to facilitate insertion of the first connector terminals T1 into the through holes 8b. The body Hi has a first surface on which the guides Ge are disposed and a second surface opposite from the first surface.

The body Hi includes frames 2a depressed from the second surface of the body Hi and exposed from the insulating member 1a sealing the body Hi. The power supply module 82 includes second connector terminals T2k. The second connector terminals T2k are female terminals fitted with the first connector terminals T1, which are male terminals. The second connector terminals T2k are bonded to the frames 2a exposed from the insulating member 1a. The first connector terminals T1 of the load are inserted into the second connector terminals T2k from above the first surface of the body Hi and the first connector terminals T1 are fitted with the second connector terminals T2k.

The body Hi of the power supply module 82 has grooves 9a shown in FIG. 32A. The second connector terminals T2K are disposed in the grooves 9a. The insulating member 1a between the grooves 9a works as walls that secure a lateral distance between the adjacent second connector terminals T2k.

The second connector terminals T2k are bonded to the frames 2a exposed from insulating member 1a in FIG. 32B by resistance welding. Thus, as shown in FIG. 30A and FIG. 31, on the first surface of the body Hi, the insulating member 1a has welding holes 5 to which electrodes for the resistance welding are inserted. The welding holes 5 have the minimum size required for insertion of the electrodes and expose surfaces of the frames 2a opposite from the surfaces shown in FIG. 30B.

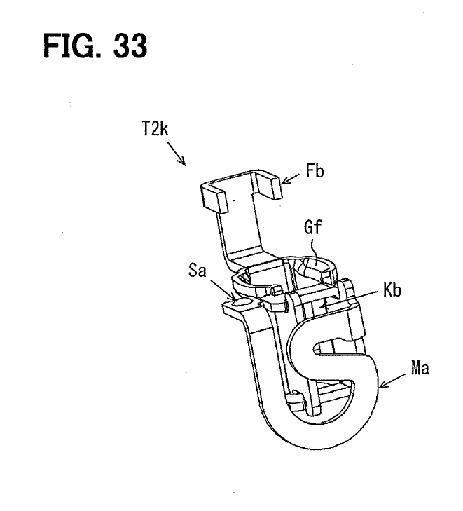

As shown in FIG. 33, the second connector terminal T2k includes a joint section Sa, a fitting section Kb, an arm section Ma, and a hook section Fb.

The fitting section Kb has a fitting structure of two contact beams. Basically, up to approximately half electric current of the four contact beams can flow in the two contact beams. In the second connector terminal T2k, when the length of the fitting section Kb coming into contact with the first connector terminal T1 is increased, the contact resistance can be reduced, and flowing current can be increased. The fitting section Kb has a guide Gf having a taper shape at an end from which the first connector terminal T1 is inserted. The guide Gf facilitates insertion of the first connector terminal T1 and leads the first connector terminal T1 to a fitting position. The guide Gf finally corrects a gap from the fitting position to which the guide Ge of the body Hi does not sufficiently introduce the first connector terminal T1.

In the second connector terminal T2k, the joint section Sa, the fitting section Kb, the arm section Ma, and the hook section Fb are integrally formed by a bending process. Thus, the second connector terminal T2k can be manufactured at a lower cost than the second connector terminal T2a.

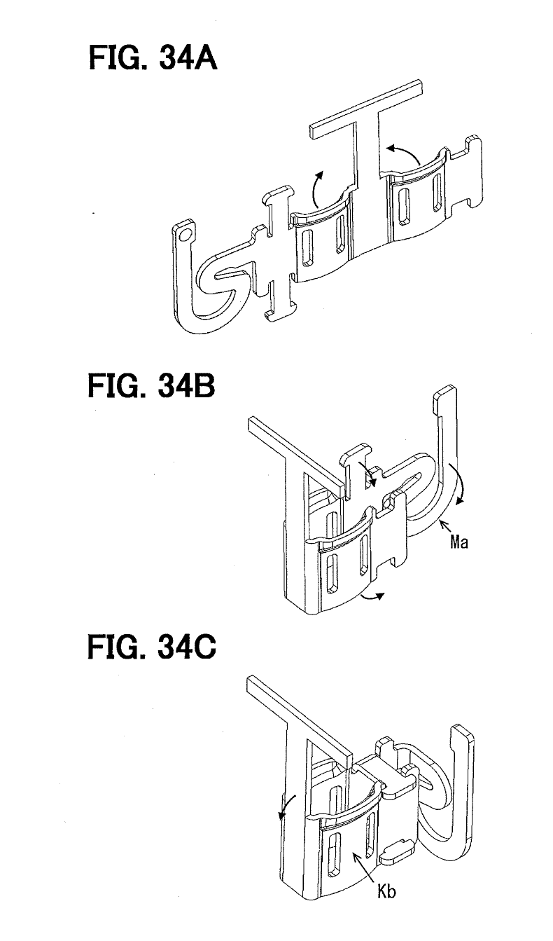

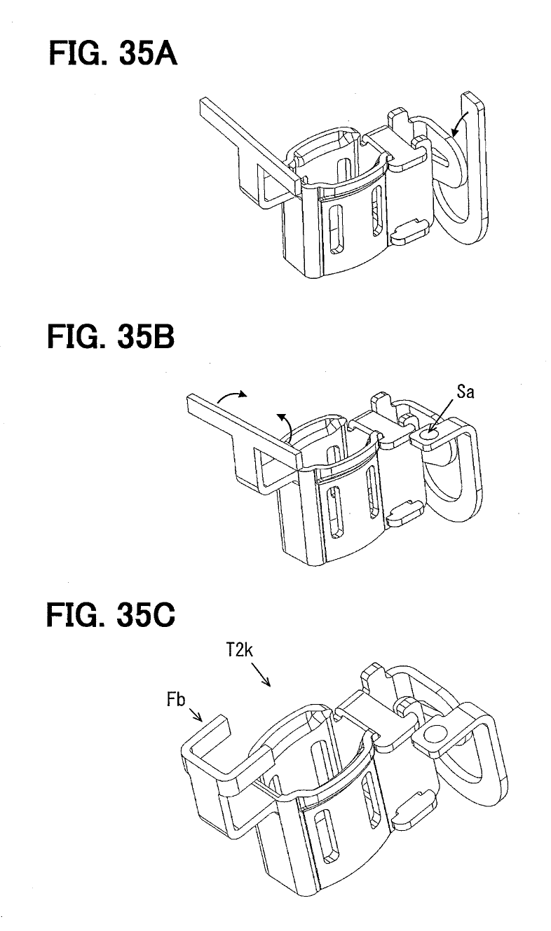

Next, a manufacturing method of the second connector terminal T2k will be described with reference to FIG. 34A to FIG. 34C and FIG. 35A to FIG. 35C.

Firstly, a base member of the second connector terminal T2k is punch-pressed to a developed shape shown in FIG. 34A. The base member is, for example, a Sn-plated copper alloy plate. The base member is treated with a bending process and the fitting section Kb is primarily formed as shown in FIG. 34B. The arm section Ma is bent at 90 degrees in a direction shown by the arrow in FIG. 34B. The second connector terminal T2k includes T-shaped hanging portions on an upper side and a lower side for maintaining a shape of the fitting section. The T-shaped hanging portions are bent in directions shown by the arrows and are hung on opposite depressed portions.

FIG. 34C is a diagram showing a state where the fitting section Kb is finally formed. Next, in order to form the hook section Fb, a connection portion with the fitting section Kb is bent in a direction shown by the arrow in FIG. 34C and the hook section Fb is primarily formed as shown in FIG. 35A.

Next, the joint section Sa is bent at 90 degrees in a direction shown by the arrow in FIG. 35A. Accordingly, the joint section Sa is formed as shown in FIG. 35B.

Then, the hook section Fb is bent in directions shown by the arrows in FIG. 35B. Accordingly, the hook section Fb is formed as shown in FIG. 35C, and the second connector terminal T2K in FIG. 33 is completed.

The second connector terminals T2k are welded to the body Hi as described below.

Firstly, the second connector terminals T2k are inserted into the body Hi and are set at predetermined position in the body Hi as shown in FIG. 30A and FIG. 30B. In this state, the second connector terminals T2k are disposed such that the hook sections Kb are caught by parts of the insulating member 1a sealing the body Hi. On the second surface side shown in FIG. 30B, the second connector terminals T2k are arranged such that the joint sections Sa are located above predetermined positions of the frames 2a exposed from the insulating member 1a.

The joint sections Sa in the second connector terminals T2k are bonded to the frames 2a by resistance welding. One welding electrode is set such that an end of the welding electrode presses the projection formed in the joint section Sa of the second connector T2k. Another welding electrode is set such that an end of the welding electrode presses the frame 2a exposed from the welding hole 5 provided in the body Hi. Then, the joint section S and the frame 2a are held between the two welding electrodes, and a large current is applied to a contact portion of a surface of the frame 2a and the joint section Sa. Accordingly, the contact portion is welded by resistance heat generated at the contact portion, and the frame 2a and the second connector terminal T2k are welded.

In the power supply modules according to the present disclosure, it is preferable that the second connector terminal is bonded to the frame exposed from the insulating member by resistance welding which provides a high joint strength in a short time. However, the second connector terminal may be bonded to the frame by another method, such as soldering.

In a case where second connector terminal T2k is bonded to the frame 2a by resistance welding, as shown in FIG. 30A and FIG. 30B, the welding hole 5, which exposes the surface of the frame 2a opposite from the surface bonded to the joint section Sa, is integrally formed in the insulating member 1a. Accordingly, an area of the frame 2a exposed from the insulating member 1a can be the minimum. However, the frame 2a may be exposed from the body Hi in another way, for example, as the power supply module 81 shown in FIG. 26A, so that two welding electrodes can be set easily.

A power supply module 83 according to a second modification of the second embodiment will be described below.

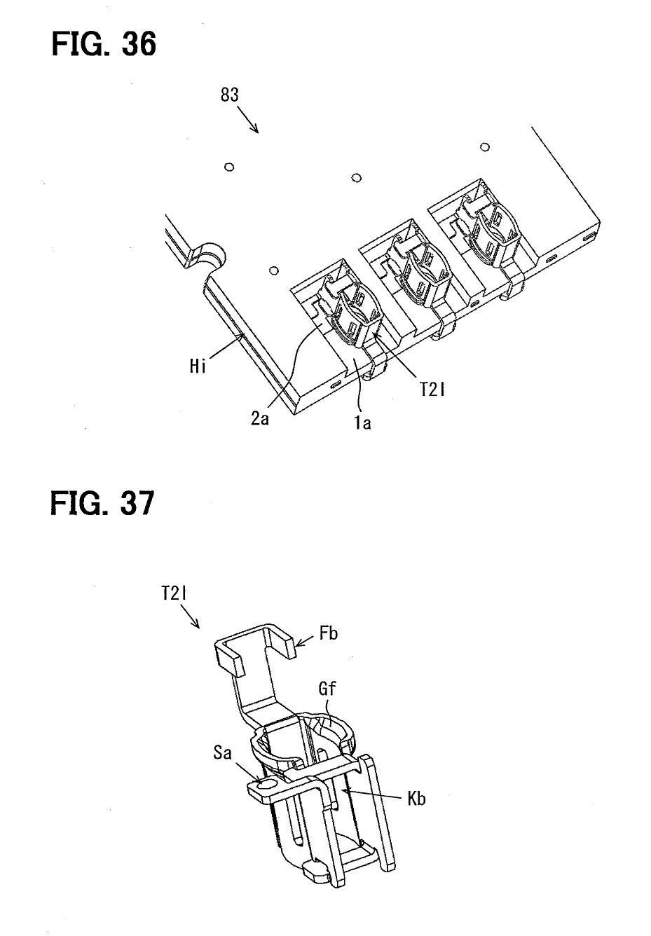

The power supply module 83 shown in FIG. 36 includes the body Hi same as the body Hi of the power supply module 82. However, second connector terminals T2l bonded to the frames 2a are different from the second connector terminals T2k of the power supply module 82.

The second connector terminal T2l shown in FIG. 37 includes the joint section Sa, the fitting section, the hook section Fb, and the guide Gf similarly to the second connector terminal T2k. However, the second connector terminal T2l does not includes the arm section Ma. The second connector terminal T2l can be used in a case where the first connector terminals of the load are arranged in line with the fitting positions.

As described above, each of the power supply modules 80-83 is configured to supply power to the load and includes the body Hh, Hi sealed with the insulating member 1a. Each of the power supply modules 80-83 can restrict displacement from the appropriate fitting position due to assembling error of the first connector terminals T1 of the load and the second connector terminals T2, T2j-T2l. In addition, each of the power supply modules 80-83 can be electrically connected with the load directly via the second connector terminals T2, T2j-T2l and can be manufactured at a low cost.

Thus, each of the power supply modules 80-83 can be suitably used for an electric compressor having an electromechanical integral structure in which the load is the driving motor 10 of the electric compressor disposed in a vehicle, and each of the power supply modules 80-83 is an inverter module that supplies power to the driving motor 10.

Because each of the power supply modules 80-83 can absorb a gap from the appropriate fitting position due to an assembling error and the like, the first connector terminals T1 of the load can be stably connected with the second connector terminals T2, T2j-T2l. Furthermore, because a lead wire or a printed circuit board does not exist on the power supply line from each of the power supply modules 80-83, the solder connection points on the power supply line via the printed circuit board and the connector, which causes a problem in the conventional power supply module 20, can be eliminated, and a size can be reduced drastically.

In each of the power supply modules 80-83, the insulating member 1a sealing the body Hh, Hi is a molded resin formed by transfer molding. As an insulating member sealing a power supply module, molded resin formed by transfer molding is widely used. However, power supply modules according to the present embodiment are not limited to power supply modules sealed with a molded resin by transfer molding and may be power supply module sealed with a ceramic package or a power supply module sealed with resin by potting.

Because the second connector terminals T2, T2j-T2l in each of the power supply modules 80-83 according to the present embodiment are attached to the body Hh, Hi of the power supply module 80-83 sealed with the insulating member 1a and are disposed outside the insulating member 1a, a degree of freedom of the shape of the second connector terminals is high. Thus, second connector terminals bonded to frames for power supply may be the female terminals in a case where first connector terminals are male terminals. In a case where first connector terminals are female terminals, second connector terminals may be male terminals. For example, frames protruding and exposed from an insulating member of a power supply module may be used as male second connector terminals, and female first connector terminals having a cylindrical shape may be introduced to the second connector terminals via through holes provided in the insulating member of the power supply module. Accordingly, the power supply module can absorb a gap from the appropriate fitting position due to assembling error of the first connector terminals and the second connector terminals. In addition, the power supply module can be electrically conned with the load directly via the first connector terminals and the second connector terminals.

What is claimed is:

1. A power supply module configured to supply power to a load having a first connector terminal, comprising:
a body including a frame for power supply;
an insulating member sealing the body such that the frame is exposed from the insulating member; and
a second connector terminal configured to be fitted with the first connector terminal and bonded to the frame.

2. The power supply module according to claim 1,
wherein the insulating member is a molded resin.

3. The power supply module according to claim 1,
wherein the second connector terminal includes a joint section, a fitting section, and an arm section, and
wherein the joint section is bonded to the frame, the fitting section is fitted with the first connector terminal, and the arm section is elastically deformable and connects the joint section and the fitting section.

4. The power supply module according to claim 3,
wherein the second connector terminal is a female terminal.

5. The power supply module according to claim 3,
wherein the joint section, the fitting section, and the arm section are integrally formed by a bending process.

6. The power supply module according to claim 4,
wherein the fitting section includes a contact piece section and a cylindrical spring section,
wherein the contact piece section includes four pieces connected at an end of the contact piece section and has a ring shape, and
wherein the cylindrical spring section has a cylindrical shape and a spring property and covers the contact piece section.

7. The power supply module according to claim 4, further comprising
a hook section integrally formed with the second connector terminal, the hook section configured to be captured by a part of the insulating member so as to restrict displacement of the fitting section when the first connector terminal is pulled out.

8. The power supply module according to claim 4,
wherein the first connector terminal is a male terminal, and
wherein the second connector terminal further includes a guide having a taper shape, and the guide is disposed at an end of the fitting section from which the first connector terminal is inserted so as to facilitate insertion of the first connector terminal.

9. The power supply module according to claim 3, further comprising
a terminal cover covering the joint section, the fitting section, and the arm section, the terminal cover fixed to the insulating member by screws.

10. The power supply module according to claim 3, further comprising:
a heat radiation member attached to the body; and
a terminal cover covering the joint section, the fitting section, and the arm section, the terminal cover fixed to the heat radiation member by screws.

11. The power supply module according to claim 9,
wherein the first connector terminal is a male terminal,
wherein the second connector terminal is a female terminal, and
wherein the terminal cover includes a guide having a taper shape so as to facilitate insertion of the first connector terminal.

12. The power supply module according claim 1,
wherein the second connector terminal is bonded to the frame by resistance welding.

13. The power supply module according to claim 12,
wherein the frame has a first surface bonded to the second connector terminal and a second surface opposite from the first surface, and
wherein the insulating member has a welding hole to which an electrode for the resistance welding is inserted, and the welding hole exposes the second surface of the frame.

14. The power supply module according to claim 1,
wherein the frame protrudes from the insulating member so as to be exposed from the insulating member.

15. The power supply module according to claim 1,
wherein the load is a driving motor of an electric compressor disposed in a vehicle, and
wherein the power supply module is an inverter module configured to supply power to the driving motor.

16. A power supply module configured to supply power to a load having a first connector terminal, comprising:
a body; and
an insulating member sealing the body and having a through hole through which the first connector terminal is inserted.

17. The power supply module according to claim 16,
wherein the insulating member is a molded resin.

18. The power supply module according to claim 16, further comprising
a guide having a taper shape, the guide disposed at an end of the through hole from which the first connector terminal is inserted so as to facilitate insertion of the first terminal.

19. The power supply module according to claim 16, further comprising
a second connector terminal configured to be fitted with the first connector terminal,
wherein the body includes a frame for power supply, and the frame is exposed from the insulating member, and
wherein the second connector terminal is bonded to the frame.

20. The power supply module according to claim 19,
wherein the second connector terminal includes a joint section, a fitting section, and an arm section, and
wherein the joint section is bonded to the frame, the fitting section is fitted with the first connector terminal, and the arm section is elastically deformable and connects the joint section and the fitting section.

21. The power supply module according to claim 20,
wherein the first connector terminal is a male terminal and the second connector terminal is a female terminal.

22. The power supply module according to claim 21,
wherein the joint section, the fitting section, and the arm section are integrally formed by a bending process.

23. The power supply module according to claim 21,
wherein the fitting section includes a contact piece section and a cylindrical spring section,
wherein the contact piece section includes four pieces connected at an end of the contact piece section and has a ring shape, and
wherein the cylindrical spring section has a cylindrical shape and a spring property and covers the contact piece section.

24. The power supply module according to claim 21, further comprising
a hook section integrally formed with the second connector terminal, the hook section configured to be captured by a part of the insulating member so as to restrict displacement of the fitting section when the first connector terminal is pulled out.

25. The power supply module according to claim 21,
wherein the second connector terminal further includes a guide having a taper shape, and the guide is disposed at an end of the fitting section from which the first connector terminal is inserted so as to facilitate insertion of the first connector terminal.

26. The power supply module according to claim 19,
wherein the second connector terminal is bonded to the frame by resistance welding.

27. The power supply module according to claim 26,
wherein the frame has a first surface bonded to the second connector terminal and a second surface opposite from the first surface, and
wherein the insulating member has a welding hole to which an electrode for the resistance welding is inserted, and the welding hole exposes the second surface of the frame.

28. The power supply module according to claim 19,
wherein the frame protrudes from the insulating member so as to be exposed from the insulating member.

29. The power supply module according to claim 16,
wherein the load is a driving motor of an electric compressor disposed in a vehicle, and
wherein the power supply module is an inverter module configured to supply power to the driving motor.
